(19) United States
(12) Patent Application Publication
(10) Pub. No.: US 2025/0062183 A1
(43) Pub. Date: Feb. 20, 2025

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventor: Sujung Hyung, Suwon-si (KR)

(21) Appl. No.: 18/787,169

(22) Filed: Jul. 29, 2024

(30) Foreign Application Priority Data
Aug. 17, 2023 (KR) 10-2023-0107749

(51) Int. Cl. H01L 23/367; H01L 21/56; H01L 23/00; H01L 23/498; H01L 25/18; H10B 80/00

(52) U.S. Cl. CPC H01L 23/3677; H01L 23/49833; H01L 23/49838; H01L 24/06; H01L 24/16; H01L 21/56; H01L 24/32; H01L 24/73; H01L 25/18; H01L 2224/06519; H01L 2224/16238; H01L 2224/32225; H01L 2224/73204; H01L 2924/1431; H10B 80/00

(57) ABSTRACT

A semiconductor package includes a first redistribution wiring layer including a chip mounting region and a connector region, and having first redistribution wirings, a plurality of first bonding pads and at least one heat dissipation pad disposed in the chip mounting region, and a plurality of second bonding pads disposed in the connector region, a semiconductor chip mounted in the chip mounting region such that a front surface on which chip pads are formed faces the first redistribution wiring layer, a molding member covering the semiconductor chip, a plurality of conductive through vias each penetrating the molding member and respectively disposed on a respective second bonding pad in the connector region, and a second redistribution wiring layer disposed on the molding member and having second redistribution wirings with at least one electrically connected to a conductive through via.

### PRIORITY STATEMENT

This application claims priority under 35 U.S.C. § 119 to Korean Patent Application No. 10-2023-0107749, filed on Aug. 17, 2023, in the Korean Intellectual Property Office (KIPO), the contents of which are herein incorporated by reference in their entirety.

### BACKGROUND

### 1. Field

Example embodiments relate to a semiconductor package and a method of manufacturing the semiconductor package. More particularly, example embodiments relate to a semiconductor package including a plurality of different chips stacked in one a package and a method of manufacturing the same.

### 2. Description of the Related Art

In a related 3D IC package-on-package (PoP) package, a lower package may include a processor chip such as a system-on-chip (SOC) provided in a mold, and may include a heat dissipation block such as a heat slug on the mold. Due to the limitation of the package size, a size of the heat dissipation block may be also limited, and a portion of a heat source area within the processor chip may not overlap with the heat dissipation block. Accordingly, there is a problem in that the thermal resistance, which prevents heat transfer from the heat source area to the outside (e.g., exterior of the package) through an upper surface of the mold, increases and heat dissipation characteristics deteriorate.

### SUMMARY

Example embodiments provide a semiconductor package having improved heat dissipation characteristics.

Example embodiments provide a method of manufacturing the semiconductor package.

According to example embodiments, a semiconductor package includes a first redistribution wiring layer including a first region and a second region that are spaced apart from each other, the first redistribution wiring layer having first redistribution wirings, a plurality of first bonding pads and at least one heat dissipation pad disposed in the first region on an upper surface of the first redistribution wiring layer, and a plurality of second bonding pads disposed in the second region on the upper surface of the first redistribution wiring layer, a semiconductor chip mounted in the first region on the first redistribution wiring layer such that a front surface on which chip pads are formed at least partially contacts the at least one heat dissipation pad, the semiconductor chip being electrically connected to the plurality of first bonding pads, a molding member covering the semiconductor chip on the first redistribution wiring layer, a plurality of conductive through vias with each conductive through via respectively penetrating the molding member on the second region and electrically connected to a respective bonding pad of the plurality of second bonding pads, and a second redistribution wiring layer disposed on the molding member and having second redistribution wirings with at least one second redistribution wiring electrically connected to a respective conductive through via of the plurality of conductive through vias.

According to example embodiments, a semiconductor package includes a first redistribution wiring layer including a chip mounting region and a connector region that are spaced apart from each other, and the first redistribution wiring layer having first redistribution wirings, a plurality of first bonding pads and a plurality of second bonding pads provided on uppermost redistribution wirings of the first redistribution wiring layers on the upper surface of the first redistribution wiring layer, the plurality of first bonding pads disposed in the chip mounting region and the plurality of second bonding pads disposed in the connector region, at least one heat dissipation pad disposed in the chip mounting region at the upper surface of the first redistribution wiring layer, a semiconductor chip mounted in the chip mounting region on the first redistribution wiring layer such that a front surface on which chip pads are formed faces the first redistribution wiring layer, the semiconductor chip being in contact with the at least one heat dissipation pad, a molding member covering the semiconductor chip on the first redistribution wiring layer, a plurality of conductive through vias respectively penetrating the molding member and each conductive through via respectively disposed on a respective second bonding pad of the plurality of second bonding pads on the connector region, and a second redistribution wiring layer disposed on the molding member and having second redistribution wirings with at least one second redistribution wiring electrically connected to a respective conductive through via of the plurality of conductive through vias.

According to example embodiments, a semiconductor package includes a first redistribution wiring layer including a chip mounting region and a connector region that are spaced apart from each other, and having first redistribution wirings, a plurality of first bonding pads and at least one heat dissipation pad respectively disposed in the chip mounting region on the first redistribution wiring layer, and a plurality of second bonding pads disposed in the connector region on the first redistribution wiring layer, a semiconductor chip mounted in the chip mounting region on the first redistribution wiring layer such that a front surface on which chip pads are formed faces the first redistribution wiring layer, a molding member covering the semiconductor chip on the first redistribution wiring layer, a plurality of conductive through vias each penetrating the molding member and respectively disposed on a respective second bonding pad of the plurality of second bonding pads in the connector region, and a second redistribution wiring layer disposed on the molding member and having second redistribution wirings with at least one electrically connected to a respective conductive through via of the plurality of conductive through vias. The semiconductor chip includes a first heating zone configured to emit first heat and a second heating zone configured to emit second heat less than the first heat. At least one dummy chip pad among the chip pads is provided in the first heating zone and contacts the at least one heat dissipation pad.

According to example embodiments, a semiconductor package may include a plurality of first bonding pads and at least one heat dissipation pad disposed in a chip mounting region on an upper surface of a first redistribution wiring layer, and a plurality of second bonding pads disposed in a connector region on the upper surface of the first redistribution wiring layer. A semiconductor chip may be mounted in the chip mounting region on the first redistribution wiring layer, and a front surface where chip pads are formed may at least partially contact the at least one heat dissipation pad. Among the chip pads of the semiconductor chip, at least one dummy chip pad may contact the at least one heat dissipation pad.

Heat from a heat source zone of the semiconductor chip provided with IP blocks such as CPU and GPU may be dissipated to the outside through the first redistribution wiring layer by the heat dissipation pad. Since heat dissipation characteristics of the semiconductor package are improved by the heat dissipation pad, a thickness of the entire package may be reduced by making a thickness of the semiconductor chip smaller.

### BRIEF DESCRIPTION OF THE DRAWINGS

Example embodiments will be more clearly understood from the following detailed description taken in conjunction with the accompanying drawings. FIGS. 1 to 29 represent non-limiting, example embodiments as described herein.

FIG. 1 is a cross-sectional view illustrating a semiconductor package in accordance with example embodiments.

FIG. 2 is a plan view illustrating the semiconductor package of FIG. 1.

FIG. 3 is a plan view illustrating a semiconductor chip and a plurality of conductive through vias in a molding member of FIG. 1.

FIG. 4 is an enlarged cross-sectional view illustrating portion ‘A’ in FIG. 1.

FIGS. 5 to 23 are views illustrating a method of manufacturing a semiconductor package in accordance with example embodiments.

FIG. 24 is a cross-sectional view illustrating a semiconductor package in accordance with example embodiments.

FIG. 25 is a cross-sectional view illustrating a semiconductor package in accordance with example embodiments.

FIG. 26 is a cross-sectional view illustrating a semiconductor package in accordance with example embodiments.

FIG. 27 is an enlarged cross-sectional view illustrating portion ‘H’ in FIG. 26.

FIG. 28 is a cross-sectional view illustrating a semiconductor package in accordance with example embodiments.

FIG. 29 is an enlarged cross-sectional view illustrating portion ‘I’ in FIG. 28.

### DETAILED DESCRIPTION OF EXAMPLE EMBODIMENTS

Hereinafter, example embodiments will be explained in detail with reference to the accompanying drawings. Embodiments described herein will be described referring to plan views and/or cross-sectional views by way of ideal schematic views. Accordingly, the exemplary views may be modified depending on manufacturing technologies and/or tolerances. Therefore, the disclosed embodiments are not limited to those shown in the views, but include modifications in configuration formed on the basis of manufacturing processes. Therefore, regions exemplified in figures may have schematic properties, and shapes of regions shown in figures may exemplify specific shapes of regions of elements to which aspects of the invention are not limited.

Items described in the singular herein may be provided in plural, as can be seen, for example, in the drawings. Thus, the description of a single item that is provided in plural should be understood to be applicable to the remaining plurality of items unless context indicates otherwise. Additionally, unless otherwise indicated, relationships between pluralities of items may include one to one, one to many, and/or many to many relationships between items of each plurality.

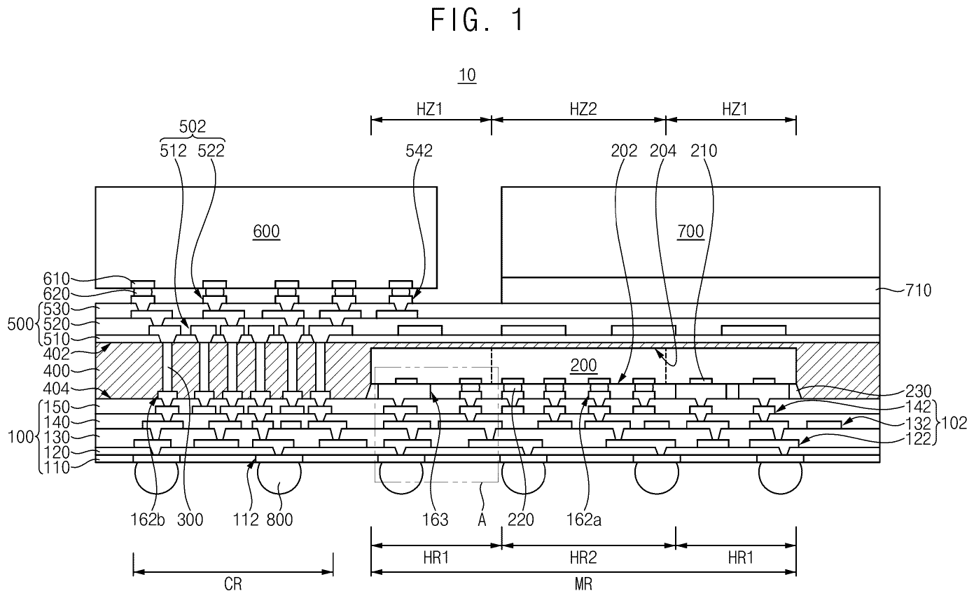

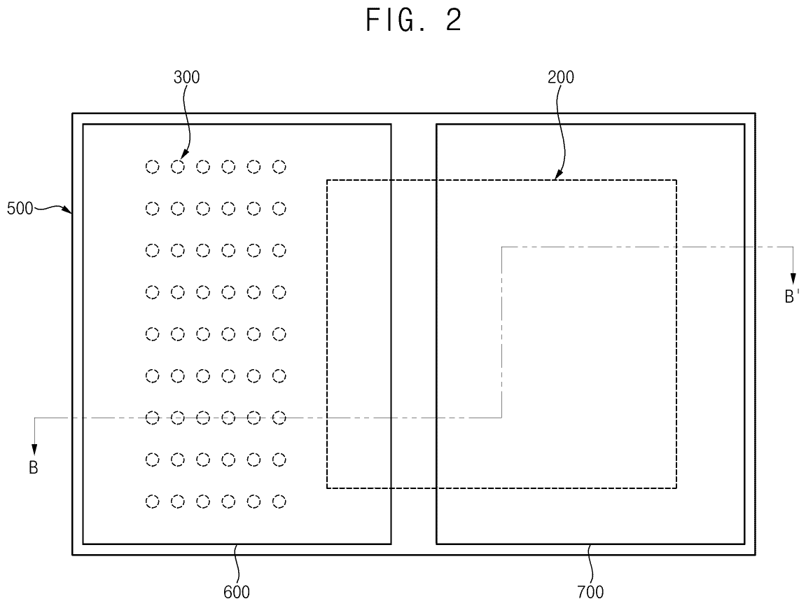

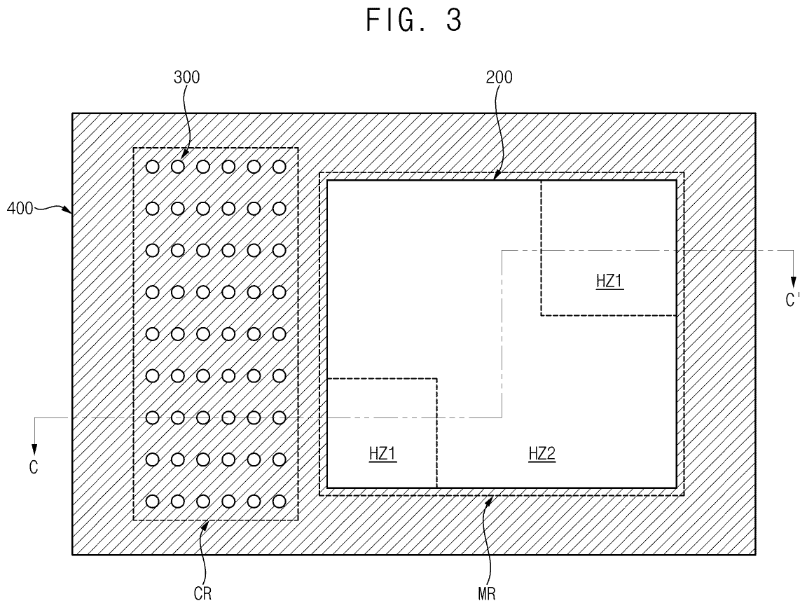

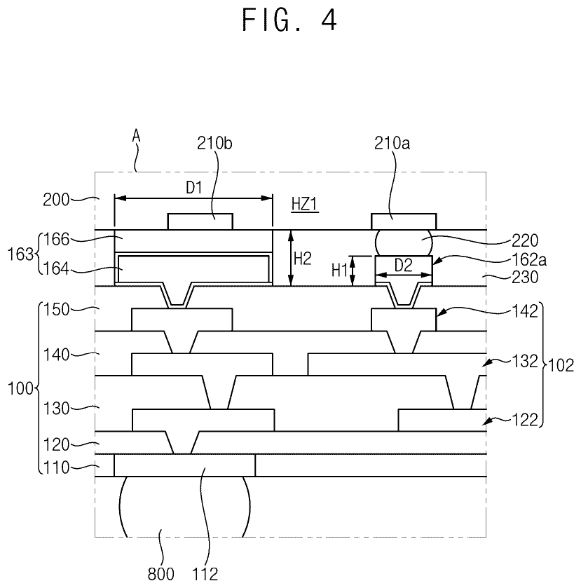

FIG. 1 is a cross-sectional view illustrating a semiconductor package in accordance with example embodiments. FIG. 2 is a plan view illustrating the semiconductor package of FIG. 1. FIG. 3 is a plan view illustrating a semiconductor chip and a plurality of conductive through vias in a molding member of FIG. 1. FIG. 4 is an enlarged cross-sectional view illustrating portion ‘A’ in FIG. 1. FIG. 1 includes a cross-section portion taken along the line B-B′ in FIG. 2 and a cross-sectional portion taken along the line C-C′ in FIG. 3.

Referring to FIGS. 1 to 4, a semiconductor package 10 may include a first redistribution wiring layer 100, a semiconductor chip 200, a plurality of conductive through vias 300, a molding member 400, and a second redistribution wiring layer 500. Additionally, the semiconductor package 10 may further include an upper semiconductor chip 600, a heat dissipation block 700, and external connection members 800.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

In example embodiments, the semiconductor package 10 may be a fan-out package in which the first redistribution wiring layer 100, which may hereafter be referred to as a lower redistribution wiring layer 100, extends to the molding member 400, which covers an outer surface of the semiconductor chip 200. The lower redistribution wiring layer 100 may be formed through a wafer-level redistribution wiring process. Additionally, the semiconductor package 10 may be provided as a unit package on which a second package is stacked.

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Additionally, the semiconductor package 10 may be used as a package on package (FO Package On Package). The semiconductor package 10 may be a multi-chip package (MCP) including different types of semiconductor chips. The semiconductor package 10 may be a system in package (SIP) having a plurality of semiconductor chips stacked or arranged in one package to perform all or most of the functions of an electronic system.

In example embodiments, the first redistribution wiring layer 100 may be a front redistribution wiring layer (FRDL) of the fan-out package and may include first redistribution wirings 102. The first redistribution wiring layer 100 may include first, second, third, fourth, and fifth lower insulating layers 110, 120, 130, 140 and 150 sequentially stacked on one another and first redistribution wirings 102 within the stacked first, second, third, fourth and fifth lower insulating layers 110, 120, 130, 140 and 150. The first redistribution wirings 102 may include first to third lower redistribution wirings 122, 132, and 142 that are vertically stacked. In some examples, a thickness of the first redistribution wiring layer 100 may be in a range of 5 μm to 50 μm.

The first redistribution wiring layer 100 may have a first surface and a second surface opposite to the first surface. The first surface may be a lower surface, and the second surface may be an upper surface. When viewed in a plan view, the first redistribution wiring layer 100 may include a first region MR and a second region CR that are arranged to be spaced apart from each other. The second region CR and the first region MR may be arranged along a first direction (e.g., an X direction). The first region MR may be a chip mounting region in which the semiconductor chip 200 is mounted on an upper surface of the first redistribution wiring layer 100 and may hereafter be referred to as a chip mounting region MR, and the second region CR may be a connector region in which the plurality of conductive through vias 300 are arranged on the upper surface of the first redistribution wiring layer 100 and may hereafter be referred to as a connection region CR. In addition, the first region MR may include a first heat dissipation region HR1 and a second heat dissipation region HR2 that respectively correspond to a first heating zone HZ1 and a second heating zone HZ2 of the semiconductor chip.

The first to fifth lower insulating layers may be formed of and/or include a polymer, a dielectric, etc. The first to fifth lower insulating layers may be a polymer layer, a dielectric layer, etc. In some examples, the first to fifth lower insulating layers may include a photosensitive insulating layer such as a photo imageable dielectric (PID). The first to fifth lower insulating layers may be formed by a vapor deposition process, a spin coating process, etc. The first redistribution wirings 102 may be formed of and/or include aluminum (Al), copper (Cu), tin (Sn), nickel (Ni), gold (Au), platinum (Pt), or an alloy thereof. The first redistribution wirings 102 may be formed by a plating process, an electroless plating process, a vapor deposition process, etc.

A first bonding pad 112 may be provided in the first lower insulating layer 110. The first bonding pad 112 may be a bump pad such as UBM (Under Bump Metallization) bump. The bump pad may include a solder pad or a pillar pad. In some examples, the first bonding pad 112 may be formed of and/or include copper (Cu), aluminum (Al), tin (Sn), nickel (Ni), gold (Au), platinum (Pt), or an alloy thereof.

The second lower insulating layer 120 may be formed on the first lower insulating layer 110, and the first lower redistribution wirings 122 may be formed on the second lower insulating layer 120. A first lower redistribution wiring 122 may be electrically connected to the first bonding pad 112 through a first opening formed in the second lower insulating layer 120.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two device, an electrically insulative underfill or mold layer, etc.) is not electrically connected to that component. Moreover, items that are “directly electrically connected,” to each other are electrically connected through one or more passive elements, such as, for example, wires, pads, internal electrical lines, conductive through vias, etc. As such, directly electrically connected components do not include components electrically connected through active elements, such as transistors or diodes. Directly electrically connected elements may be directly physically connected and directly electrically connected.

The third lower insulating layer 130 may be formed on the second lower insulating layer 120, and the second lower redistribution wirings 132 may be formed on the third lower insulating layer 130. A second lower redistribution wiring 132 may be electrically connected to a first lower redistribution wiring 122 through a second opening formed in the third lower insulating layer 130.

The fourth lower insulating layer 140 may be formed on the third lower insulating layer 130, and the third lower redistribution wirings 142 may be formed on the third lower insulating layer 130. A third lower redistribution wiring 142 may be electrically connected to a second lower redistribution wiring 132 through a third opening formed in the third lower insulating layer 130.

The fifth lower insulating layer may be a solder resist layer 150 formed on the fourth lower insulating layer 140 and may have openings that expose portions of the third lower redistribution wirings 142. Upper bonding pads such as UBM pads may be disposed on the exposed portions of the third lower redistribution wirings 142 as uppermost redistribution wirings. The solder resist layer 150 may function as a passivation layer.

It will be understood that the number and arrangement of the lower insulating layers and the lower redistribution wirings of the lower redistribution wiring layer are provided as examples, and the present inventive concept is not limited thereto.

In example embodiments, the uppermost redistribution wirings 142 of the first redistribution wirings 102 may include first uppermost redistribution wirings disposed in the first heat dissipation region HR1 of the first region MR, second uppermost redistribution wirings disposed in the second heat dissipation region HR2 of the first region MR, and third uppermost redistribution wirings disposed in the second region CR.

The upper bonding pads may include a plurality of first bonding pads 162a and at least one heat dissipation pad 163 disposed in the first region MR, and a plurality of second bonding pads 162b disposed in the second region CR. The plurality of first bonding pads 162a may be respectively disposed on the first uppermost redistribution wirings. The at least one heat dissipation pad 163 may be disposed on at least one of the second uppermost redistribution wirings. The plurality of second bonding pads 162b may be respectively disposed on the third uppermost redistribution wirings.

In example embodiments, the semiconductor chip 200 may be arranged in the first region MR of the first redistribution wiring layer 100. The semiconductor chip 200 may be mounted on the upper surface of the first redistribution wiring layer 100 by a flip chip bonding method. The semiconductor chip 200 may be arranged such that a front surface 202 on which chip pads 210 are formed, that is, an active surface faces the first redistribution wiring layer 100.

The semiconductor chip may be a logic chip including logic circuits. The logic chip may be a controller that controls memory chips. The semiconductor chip may be ASIC serving as a host such as CPU, NPU, GPU, or SOC, or a processor chip such as an application processor AP. For example, when the semiconductor chip is provided for a mobile AP, the semiconductor chip may be a system on chip (SOC) that includes IP blocks such as CPU, GPU, etc. in one chip.

As illustrated in FIG. 3, the semiconductor chip 200 may include at least one first heating zone HZ1 configured to emit first heat and a second heating zone HZ2 configured to emit second heat that is less than the first heat. The first heating zone HZ1 may include the IP block and may be a heat source area of the semiconductor chip 200 that emits a relatively large amount of heat. The semiconductor chip 200 may be disposed on the first redistribution wiring layer 100 such that the first heating zone HZ1 and the second heating zone HZ2 of the semiconductor chip 200 respectively correspond to the first heat dissipation region HR1 and the second heat dissipation region HR2 of the first region MR1 of the first redistribution wiring layer 100.

The chip pads 210 of the semiconductor chip 200 may include signal chip pads 210a and dummy chip pads 210b. The signal chip pads 210a may be chip pads through which electrical signals and/or voltage are transmitted (e.g., connected to one or more circuits within the semiconductor chip 200 configured to receive and transmit signals or voltage), and the dummy chip pads 210b may be dummy chip pads through which electrical signals and voltage are not transmitted (e.g., not connected to any circuitry within the semiconductor chip 200 that transmits or receives signals or voltage). At least one dummy chip pad 210b may be formed in the first heating zone HZ1 on the front surface 202 of the semiconductor chip 200. The signal chip pads 210a may be formed in the first heating zone HZ1 and the second heating zone HZ2 on the front surface 202 of the semiconductor chip 200.

In example embodiments, the semiconductor chip 200 may be electrically connected to the first redistribution wirings 102 of the first redistribution wiring layer 100 via conductive bumps 220. The conductive bumps 220 may include micro bumps (uBumps). The conductive bumps 220 may be formed respectively on the signal chip pads 210a. The conductive bump 220 may be interposed between the signal chip pad 210a and the first bonding pad 162a. In this case, the signal chip pad 210a may include a pillar pad, and the conductive bump 220 may include a solder pad formed on the pillar pad. The pillar pad may be formed of and/or include copper (Cu), nickel (Ni), palladium (Pd), platinum (Pt), gold (Au), cobalt (Co), or an alloy thereof. The solder pad may be formed of and/or include tin (Sn), indium (In), antimony (Sb), copper (Cu), silver (Ag), zinc (Zn), lead (Pb), or an alloy thereof.

The semiconductor chip 200 may be disposed so that at least one dummy chip pad 210b contacts a heat dissipation pad 163. The semiconductor chip 200 may be disposed on the first redistribution wiring layer 100 such that the front surface 202 at least partially contacts the at least one heat dissipation pad 163. The dummy chip pad 210b may contact the heat dissipation pad 163. Accordingly, heat from the first heating zone HZ1 of the semiconductor chip 200 may be transferred to the first heat dissipation region HR1 of the redistribution wiring layer 100 through the dummy chip pad 210b and the heat dissipation pad 163 and may then be dissipated to the outside (external to the semiconductor package 10).

As illustrated in FIG. 4, the heat dissipation pad 163 may be provided on the first uppermost redistribution wiring 142 disposed in the first heat dissipation region HR1 of the first region MR. The heat dissipation pad 163 may include a lower heat dissipation pad 164 and an upper heat dissipation pad 166 sequentially stacked on the first uppermost redistribution wiring 142. A diameter D1 or width of the heat dissipation pad 163 may be greater than a diameter D2 or width of the first bonding pad 162a. For example, for effective heat dissipation, the diameter D1 of the heat dissipation pad 163 may be at least twice as great as the diameter D2 of the first bonding pad 162a. The diameter D1 of the heat dissipation pad 163 may be within a range of 2 m to 500 μm. The heat dissipation pad 163 may be formed of and/or include a metal material with excellent thermal conductivity. The heat dissipation pad 163 may be formed of and/or include the same material as the lower redistribution wiring. The heat dissipation pad 163 may be formed of and/or include copper (Cu). A height H2 of the heat dissipation pad 163 from the first redistribution wiring layer 100 may be greater than a height H1 of the first bonding pad 162a from the first redistribution wiring layer 100. Electrical signals may be transmitted through the first and second bonding pads 162a and 162b. The heat dissipation pad 163 may be a dummy pad through which electrical signals are not transmitted.

In some examples, a thickness of the semiconductor chip 200 may be within a range of 100 μm to 300 μm. Heat from the first heating zone HZ1 of the semiconductor chip 200 may be effectively dissipated to the outside through the dummy heat dissipation pads 163. The heat dissipation characteristics of the semiconductor package 10 may be improved by the heat dissipation pads 163 and an entire thickness of the package may be reduced by reducing the thickness of the semiconductor chip 200, which is possible due to the improved heat dissipation characteristics.

Underfill members 230 may be underfilled between the semiconductor chip 200 and the first redistribution wiring layer 100. The underfill member may include a material with relatively high fluidity when applied to effectively fill a small space between the semiconductor chip and the first redistribution wiring layer. In some examples, the underfill member may include an adhesive containing an epoxy material.

It will be understood that the thicknesses of the first redistribution wiring layer and the semiconductor chip, the arrangements of the conductive through vias and the heat dissipation pads, etc. are provided as examples, and the present inventive concept is not limited thereto. The thicknesses of the first redistribution wiring layer and the semiconductor chip, the arrangements of the conductive through vias and the heat dissipation pads, etc. may be determined in consideration of the thickness, warpage, heat dissipation characteristics, etc. of the entire package.

In example embodiments, the plurality of conductive through vias 300 may be disposed on the second region CR of the first redistribution wiring layer 100. Each of the conductive through vias 300 may extend upward from a respective second bonding pad 162b on the first redistribution wirings 102 of the first redistribution wiring layer 100 (e.g., the third uppermost redistribution wirings 142). The conductive through vias 300 may be formed to penetrate through the molding member 400. The conductive through vias 300 may be electrically connected to the first redistribution wirings 102.

In some examples, a diameter of a conductive through via 300 may be within a range of 30 μm to 100 μm, and a height of a conductive through via 300 from the first redistribution wiring layer 100 may be within a range of 200 μm to 300 μm. The conductive through vias 300 may be formed of and/or include a metal such as copper. The thickness of the first redistribution wiring layer 100 of the semiconductor chip 200 may be less than the heights of the conductive through vias 300.

As illustrated in FIG. 3, the first redistribution wiring layer 100 may have a rectangular shape with a long side in a first direction (e.g., an X direction) and a short side in a second direction (e.g., a Y direction) perpendicular to the first direction. The first redistribution wiring layer 100 may have an area in a plan view of 15 mm×14 mm or more. The semiconductor chip 200 may have an area in a plan view of 7 mm×10 mm or more.

It will be understood that lengths of the short and long sides of the first redistribution wiring layer, the lengths and heights of short and long sides of the semiconductor chip, the arrangements of the conductive through vias, etc. are provided as examples, and the present inventive concept is not limited thereto. The lengths of the short and long sides of the first redistribution wiring layer, the lengths and heights of the short and long sides of the semiconductor chip, and the arrangements of the conductive through vias may be determined in consideration of the thickness, warpage, and heat dissipation characteristics of the entire package.

In example embodiments, the molding member 400 may cover the semiconductor chip 200 and the conductive through vias 300 on the upper surface of the first redistribution wiring layer 100. An upper surface of the semiconductor chip 200 may be covered by the molding member 400. Upper surfaces of the conductive through vias 300 may be exposed at an upper surface 402 of the molding member 400.

In some examples, the molding member 400 may be formed of and/or include an epoxy mold compound (EMC). The molding member 400 may be formed of and/or include UV resin, polyurethane resin, silicone resin, silica filler, etc.

In example embodiments, the second redistribution wiring layer 500 may be a backside redistribution wiring layer (BRDL) and may be disposed on the molding member 400. The second redistribution wiring layer 500 may include second redistribution wirings 502. The second redistribution wirings 502 may be electrically connected to the conductive through vias 300. The second redistribution wiring layer 500 may cover the entire upper surface 402 of the molding member 400. The second redistribution wiring layer 500 may be disposed on the semiconductor chip 200. The second redistribution wiring layer 500 may be arranged to overlap the plurality of conductive through vias 300.

The second redistribution wiring layer 500 may include first, second, and third upper insulating layers 510, 520, and 530 sequentially stacked on one another and the second redistribution wirings 502 in the first, second and third upper insulating layers 510, 520 and 530. The second redistribution wirings 502 may include first and second upper redistribution wirings 512 and 522.

The third upper insulating layer 530 may have openings that expose portions of the second upper redistribution wirings 522, respectively. The portions of the second upper redistribution wirings 522 exposed by the openings may be uppermost redistribution wirings. A portion of the uppermost redistribution wiring may include a redistribution pad portion. An upper bump pad 542 such as a UBM pad may be formed on the redistribution pad portion.

It will be understood that the number, sizes, and arrangements of the upper insulating layers and the upper redistribution wirings of the second redistribution wiring layer are provided as examples, and the present inventive concept is not limited thereto.

In example embodiments, the semiconductor package 10 may include a lower package and an upper package stacked on the lower package. The lower package may include the first redistribution wiring layer 100, the semiconductor chip 200, the plurality of conductive through vias 300, the molding member 400, and the second redistribution wiring layer 500. The upper package may be disposed on the second redistribution wiring layer 500 of the lower package.

The upper semiconductor chip 600 may be a component of the upper package and may be stacked on the second redistribution wiring layer 500. The upper semiconductor chip 600 may be mounted on an upper surface of the second redistribution wiring layer 500 by a flip chip bonding method. The upper semiconductor chip 600 may be disposed such that a front surface, at which upper chip pads 610 are formed, that is, an active surface, faces the second redistribution wiring layer 500. The upper chip pads 610 of the upper semiconductor chip 600 may be electrically connected to the second redistribution wirings 502 of the second redistribution wiring layer 500 through second conductive bumps 620.

The upper semiconductor chip 600 may be arranged to partially overlap the plurality of conductive through vias 300. Examples of the upper semiconductor chip 600 may include a memory chip. The memory chip may include various types of memory circuits, such as DRAM, SRAM, flash, PRAM, ReRAM, FeRAM, or MRAM.

Although the upper package is illustrated as one upper semiconductor chip being mounted on the second redistribution wiring layer 500, embodiments are not limited thereto.

For example, the upper package may include a package substrate and at least one upper semiconductor chip mounted on the package substrate, and the package substrate of the upper package may be mounted on the second redistribution wiring layer via the third conductive bumps.

In example embodiments, the heat dissipation block 700 may be a component of the upper package and may be disposed on the second redistribution wiring layer 500. The heat dissipation block 700 may be disposed to a side of the upper semiconductor chip 600 on the second redistribution wiring layer 500. The heat dissipation block 700 may be arranged to be spaced apart from the upper semiconductor chip 600 on the second redistribution wiring layer 500.

The heat dissipation block 700 may be disposed above the lower semiconductor chip 200. The heat dissipation block 700 may be arranged to partially overlap the semiconductor chip 200 in a vertical direction. When viewed in a plan view, one side of the semiconductor chip 200 nearest the conductive through vias 300 may be exposed such that the one side is not immediately below the heat dissipation block 700 (e.g., the one side of the semiconductor chip 200 may not vertically overlap with the heat dissipation block 700). When the heat source area where heat is concentrated during use, such as a CPU or GPU block, is provided on the one side of the semiconductor chip 200, the heat source area does not overlap with the heat dissipation block 700 and thermal resistance through the second redistribution wiring layer 500 may be higher relative to the area that overlaps the heat dissipation block 700. The heat from the heat source area may not be readily dissipated through the heat dissipation block 700 due to the higher thermal resistance. Instead, the heat from the heat source area of the semiconductor chip 200 may be effectively dissipated to the outside (e.g., external to the semiconductor package 10) through the first redistribution wiring layer 100 by the dummy heat dissipation pads 163. Accordingly, the heat dissipation characteristics of the semiconductor package 10 may be improved.

The heat dissipation block 700 may be attached to the upper surface of the second redistribution wiring layer 500 by an adhesive film 710 such as a non-conductive adhesive film (NCF). In some examples, the heat dissipation block 700 may be formed of and/or include a material with excellent thermal conductivity. The heat dissipation block 700 may be formed of and/or include a metal such as copper or a silicon material. A height of the heat dissipation block 700 from the second redistribution wiring layer 500 may be the same as a height of the upper semiconductor chip 600 from the second redistribution wiring layer 500. A thickness of the upper semiconductor chip 600 may be within a range of 0.3 mm to 0.5 mm, and a thickness of the first heat dissipation block 700 may be within a range of 0.4 mm to 0.65 mm. A diameter of each of the second conductive bumps 620 may be within a range of 70 μm to 200 μm.

As illustrated in FIG. 2, the second redistribution wiring layer 500 may have a rectangular shape with a long side in a first direction (e.g., the X direction) and a short side in a second direction (e.g., the Y direction) perpendicular to the first direction. The second redistribution wiring layer 500 may have an area of 15 mm×14 mm or more.

In example embodiments, the external connection members 800 for electrical connection with an external device may be disposed on the lower bonding pads 112 on the lower surface of the first redistribution wiring layer 100. In some examples, the external connection member 800 may be a solder ball or solder bump. The semiconductor package 10 may be mounted on a module substrate (not illustrated) or an interposer via the solder balls or the solder bumps.

As mentioned above, the semiconductor package 10 may include the plurality of first bonding pads 162a and the at least one heat dissipation pad 163 disposed on the uppermost redistribution wirings 142 in the chip mounting region MR on the upper surface of the first redistribution wiring layer 100, and the plurality of second bonding pads 162b disposed in the connector region CR on the upper surface of the first redistribution wiring layer 100. The semiconductor chip 200 may be mounted in the chip mounting region MR on the first redistribution wiring layer 100, and the front surface 202 where the chip pads 210 are formed may at least partially contact the at least one heat dissipation pad 163. Among the chip pads 210 of the semiconductor chip 200, the at least one dummy chip pad 210b may contact the at least one heat dissipation pad 163.

Heat from the first heating zone HZ1 of the semiconductor chip 200 provided with IP blocks such as CPU and GPU may be dissipated to the outside through the first redistribution wiring layer 100 by the heat dissipation pad 163. Since the heat dissipation characteristics of the semiconductor package 10 are improved by the heat dissipation pad 163, the thickness of the entire package may be reduced by making the thickness of the semiconductor chip 200 smaller.

Hereinafter, a method of manufacturing the semiconductor package of FIG. 1 will be described.

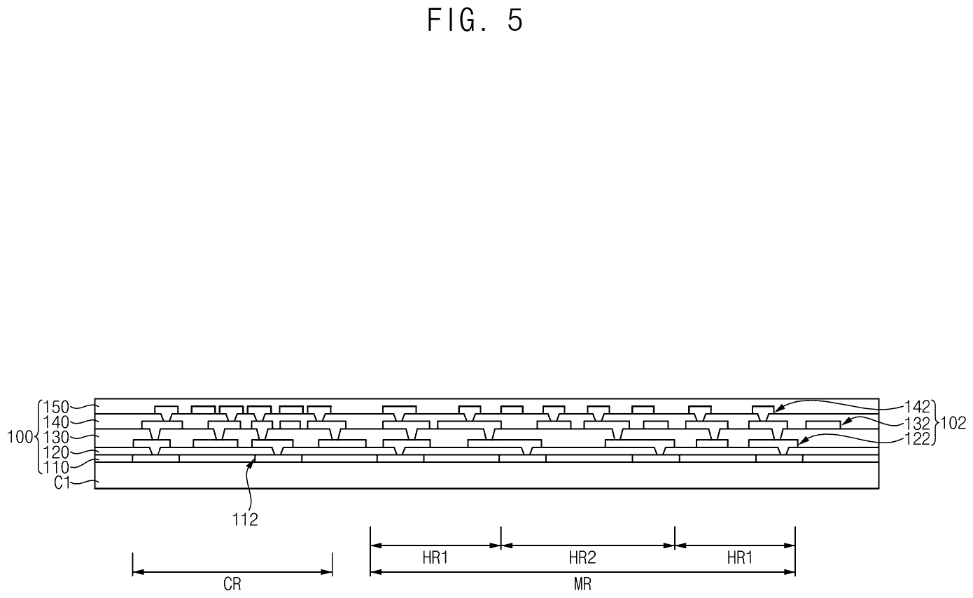

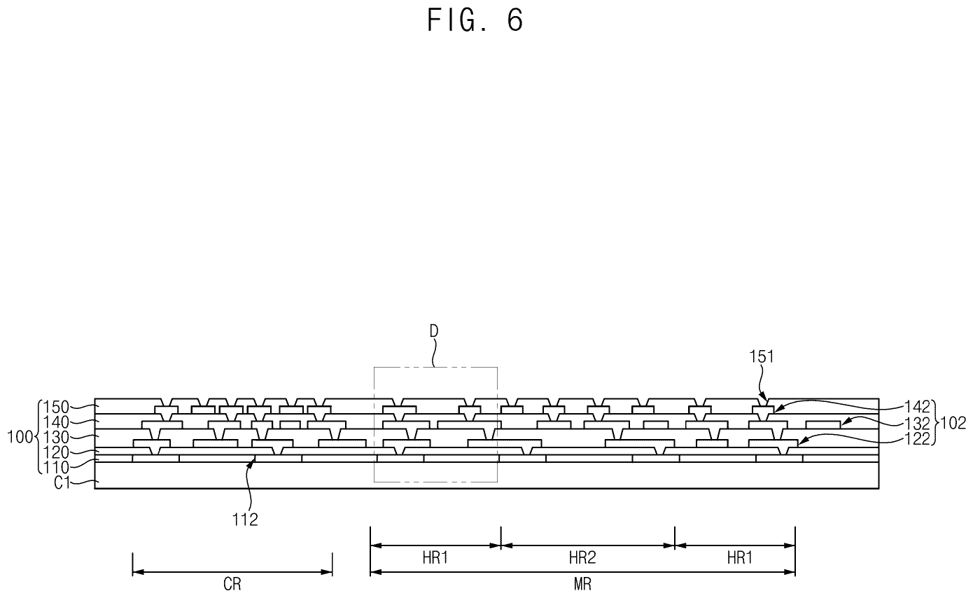

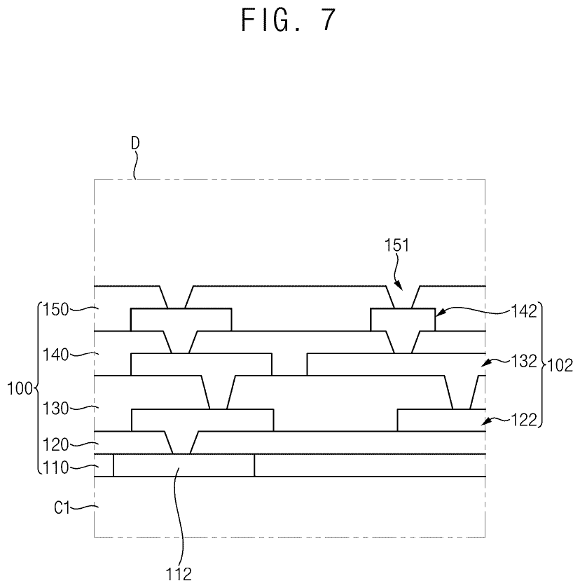

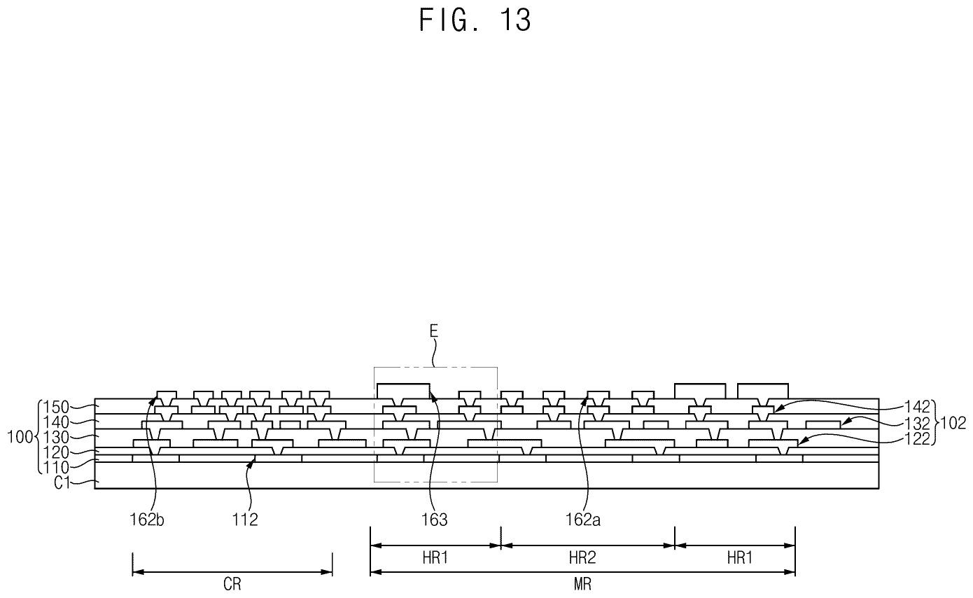

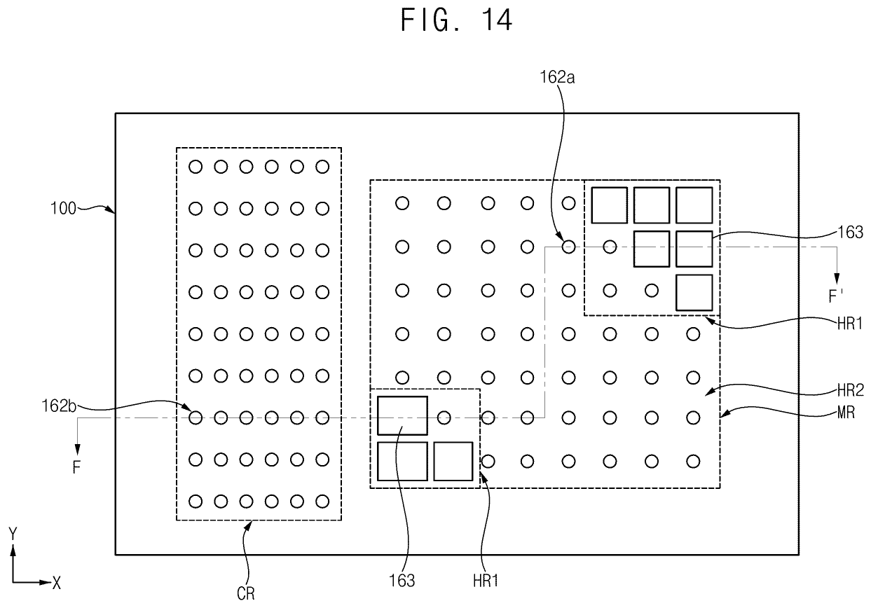

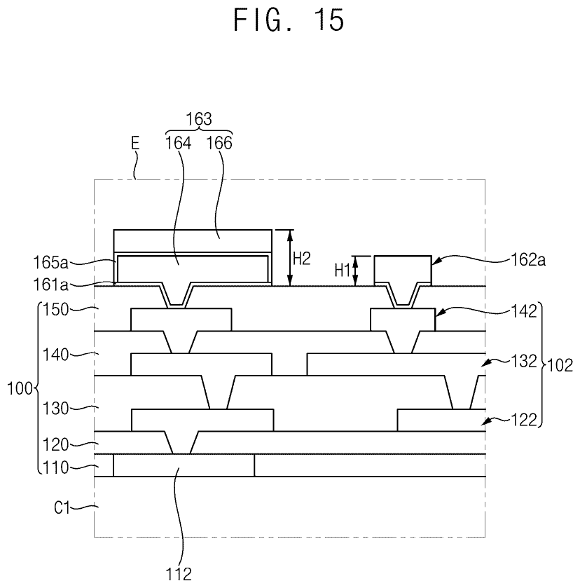

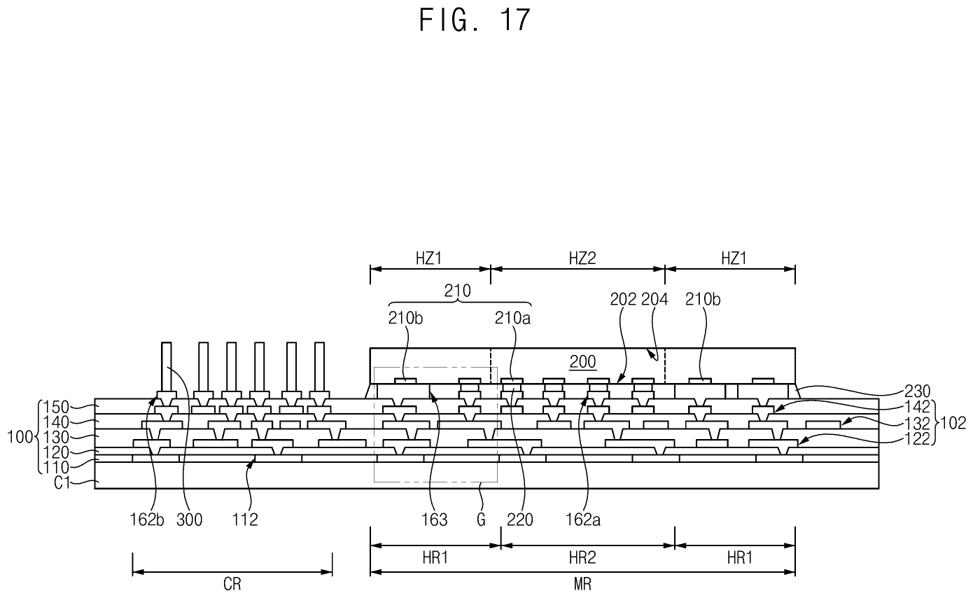

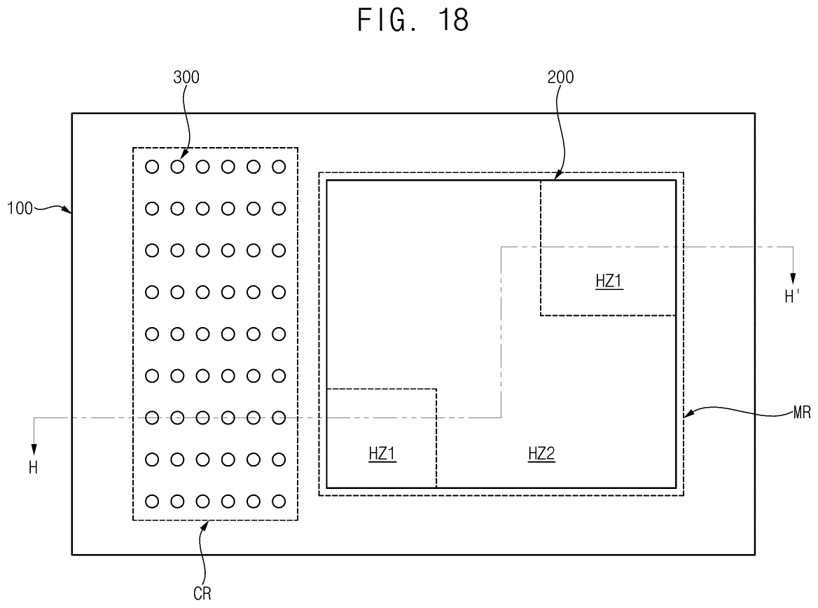

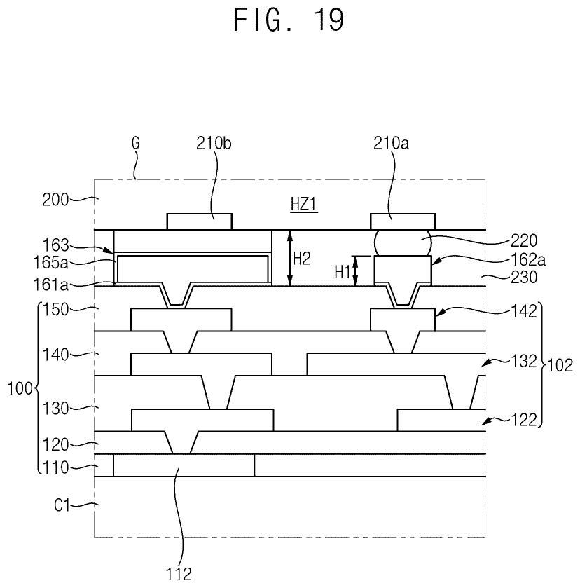

FIGS. 5 to 23 are views illustrating a method of manufacturing a semiconductor package in accordance with example embodiments. FIGS. 5, 6, 13, 16, 17, and 20 to 23 are cross-sectional views illustrating a method of manufacturing a semiconductor package in accordance with example embodiments. FIGS. 7 to 12 are enlarged cross-sectional views illustrating portion ‘D’ in FIG. 6. FIG. 14 is a plan view of FIG. 13. FIG. 15 is an enlarged cross-sectional view illustrating portion ‘E’ in FIG. 13. FIG. 18 is a plan view of FIG. 17. FIG. 19 is an enlarged cross-sectional view illustrating portion ‘G’ in FIG. 17. FIG. 13 is a cross-sectional view taken along the line F-F′ in FIG. 14. FIG. 17 is a cross-sectional view taken along the line H-H′ in FIG. 18.

Referring to FIG. 5, a first redistribution wiring layer 100 may be a lower redistribution wiring layer having first redistribution wirings 102 and may be formed on a carrier substrate C1.

In example embodiments, the carrier substrate C1 may include a wafer substrate which may be a base substrate, and a plurality of semiconductor chips may be disposed on a lower redistribution wiring layer formed on the carrier substrate C1. A molding member may be formed to cover the plurality of semiconductor chips. The carrier substrate C1 may have a shape corresponding to a wafer on which a semiconductor process is performed. In some examples, the carrier substrate C1 may include a silicon substrate, a glass substrate, a non-metallic or metallic plate, etc.

A first lower insulating layer 110 with lower bonding pads 112 may be formed on the carrier substrate C1. Although not illustrated in the figures, after a release film, a barrier metal layer, a seed layer, and the lower are formed on the carrier substrate C1, the first lower insulating layer may be patterned to form an opening exposing a lower bonding pad region. Subsequently, a plating process may be performed on the seed layer to form the lower bonding pads 112 in the openings.

In some examples, the first lower insulating layer 110 may be formed of and/or include a polymer, a dielectric, etc. The first lower insulating layer 110 may include a polymer layer, a dielectric layer, etc. The first lower insulating layer 110 may include an insulating layer such as a photosensitive insulating material PID or Ajinomoto Build-Up Film ABF. The first lower insulating layer 110 may be formed by a spin coating process, a vapor deposition process, etc.

The lower bonding pad 112 may be a bump pad. Examples of the bump pad may include a solder pad and/or a pillar pad. In some examples, the lower bonding pad 112 may be formed of and/or include copper (Cu), aluminum (Al), tin (Sn), nickel (Ni), gold (Au), platinum (Pt), or an alloy thereof.

A second lower insulating layer 120 may be formed on the first lower insulating layer 110 to cover the lower bonding pads 112, and then the second lower insulating layer 120 may be patterned to form first openings that expose at least portions of the lower bonding pads 112.

Examples of the second lower insulating layer 120 may include a polymer layer, a dielectric layer, etc. The second lower insulating layer 120 may include an insulating layer such as PID or ABF. The second lower insulating layer 120 may be formed by a spin coating process, a vapor deposition process, etc.

First lower redistribution wirings 122 may be formed on the second lower insulating layer 120 and may be electrically connected to the lower bonding pads 112 through the first openings, respectively.

In some examples, the first lower redistribution wirings 122 may be formed by forming a seed layer on a portion of the second lower insulating layer 120 and in the first opening, then patterning the seed layer, and performing an electrolytic plating process. Accordingly, at least a portion of the first lower redistribution wirings 122 may contact the lower bonding pad 112 through the first opening.

Similarly, a third lower insulating layer 130 may be formed on the second lower insulating layer 120 to cover the first lower redistribution wirings 122, and the third lower insulating layer 130 may be patterned to form second openings that expose at least portions of the first lower redistribution wirings 122. Subsequently, second lower redistribution wirings 132 may be formed on the third lower insulating layer 130 and may be electrically connected to the first lower redistribution wirings 122 through the second openings, respectively.

A fourth lower insulating layer 140 may be formed on the third lower insulating layer 130 to cover the second lower redistribution wirings 132, and the fourth lower insulating layer 140 may be patterned to form third openings that expose at least portions of the second lower redistribution wirings 132. Subsequently, third lower redistribution wirings 142 may be formed on the fourth lower insulating layer 140 to contact the second lower redistribution wirings 132 through the third openings.

A fifth lower insulating layer 150 may be formed on the fourth lower insulating layer 140 to cover the third lower redistribution wirings 142 in a similar manner.

Using the described process the lower redistribution wiring layer 100 having the first to fifth lower insulating layers 110, 120, 130, 140, and 150 may be formed. The lower redistribution wiring layer 100 may be a front redistribution wiring layer (FRDL) of a fan-out package. The lower redistribution wiring layer 100 may include first redistribution wirings 102 stacked in at least two layers. The lower bonding pads 112 may be exposed from a lower surface of the lower redistribution wiring layer 100. The first redistribution wirings 102 may include first, second, and third lower redistribution wirings 122, 132 and 142 that are vertically stacked. In some examples, a thickness of the first redistribution wiring layer 100 may be within a range of 5 μm to 50 μm.

The first redistribution wiring layer 100 may include a first region MR and a second region CR arranged to be spaced apart from each other along a first direction. As will be described later, when viewed in plan view, the first region MR may be a chip mounting region that overlaps the semiconductor chip mounted on the upper surface of the first redistribution wiring layer 100, and the second region CR may be a connector region that overlaps a plurality of conductive through vias disposed on the upper surface of the redistribution wiring layer 100.

Additionally, the first region MR may include a first heat dissipation region HR1 and a second heat dissipation region HR2 that respectively correspond to a first heating zone and a second heating zone of the semiconductor chip.

The third lower redistribution wirings 142, which are uppermost redistribution wirings of the first redistribution wiring 102 may include first uppermost redistribution wirings disposed in the first heat dissipation region HR1 of the first region MR, second uppermost redistribution wirings disposed in the second heat dissipation region HR2 of the first region MR disposed in the second heat dissipation region HR2 and electrically connected to signal chip pads among chip pads of the semiconductor chip, and third uppermost redistribution wirings disposed in the second region CR and electrically connected to a plurality of conductive through vias. As will be described later, heat dissipation pads may be formed on the first uppermost redistribution wirings, and upper bonding pads such as UBM may be formed on the second and third uppermost redistribution wirings.

Additionally, the second and third uppermost redistribution wirings may be electrically connected to each other. The second and third uppermost redistribution wirings may be electrically connected to each other through another redistribution wiring of the first redistribution wirings 102 such as the second lower redistribution wirings 132. Accordingly, the semiconductor chip and the conductive through vias may be electrically connected to each other through the first redistribution wirings 102.

It will be understood that the number, sizes, and arrangements of the lower insulating layers and the lower redistribution wirings of the first redistribution wiring layer 100 are provided as examples, and the present inventive concept is not limited thereto.

Referring to FIGS. 6 to 15, a plurality of first bonding pads 162a, a plurality of second bonding pads 162b, and at least one heat dissipation pad 163 which may act as upper bonding pads may be formed on the upper surface of the first redistribution wiring layer 100.

As illustrated in FIGS. 6 and 7, the fifth lower insulating layer 150 may be patterned to form openings 151 that expose the third lower redistribution wirings 142. The third lower redistribution wirings 142 exposed by the openings 151 may be uppermost redistribution wirings. A portion of the uppermost redistribution wiring may include a redistribution pad portion.

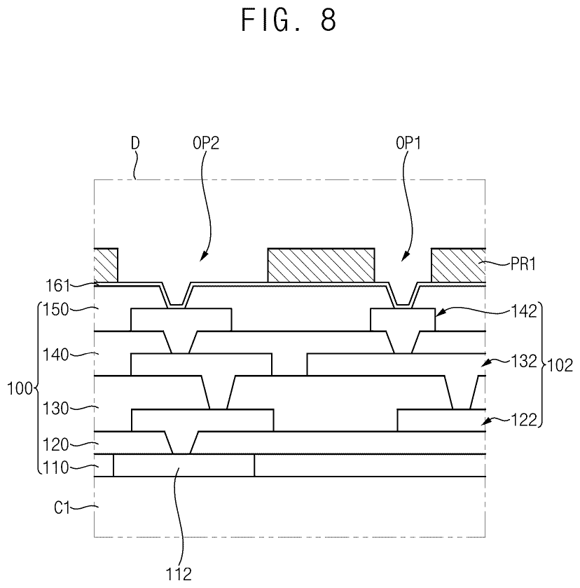

As illustrated in FIG. 8, a first seed layer 161 may be formed on the fifth lower insulating layer 150, and a first photoresist pattern PR1 having openings that expose upper bonding pad regions may be formed on the first seed layer 161. The openings may include first openings OP1 that expose first bonding pad regions in the first region MR, second openings OP2 that expose heat dissipation pad regions in the first region MR, and third openings that expose second bonding pad regions in the connection region CR.

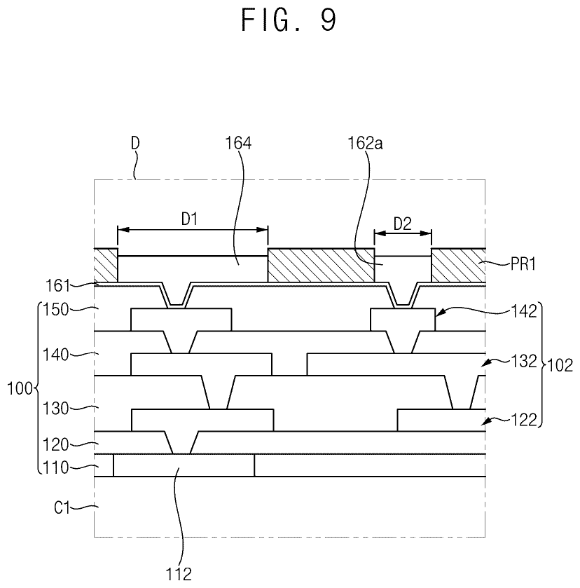

As illustrated in FIG. 9, upper bonding pads may be formed in the openings of the first photoresist pattern PR1 by a plating process. The upper bonding pads may be formed of and/or include a metal material. The upper bonding pads may be formed of and/or include the same material as the third lower redistribution wiring 142. The upper bonding pads may be formed of and/or include copper (Cu).

The upper bonding pads may include the plurality of first bonding pads 162a formed in the first openings OP1 and the plurality of second bonding pads 162b formed in the third openings (see FIG. 13). A lower heat dissipation pad 164 may be formed in the second opening OP2 of the first photoresist pattern PR1. A diameter D1 of the lower heat dissipation pad 164 may be greater than a diameter D2 of the first bonding pad 162a. The diameter D1 of the lower heat dissipation pad 164 may be at least twice as great as the diameter D2 of the first bonding pad 162a. The diameter D1 of the lower heat dissipation pad 164 may be within a range of 2 μm to 500 μm.

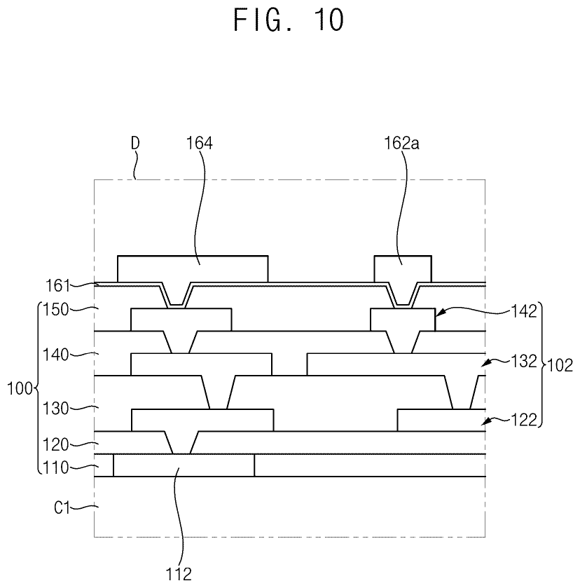

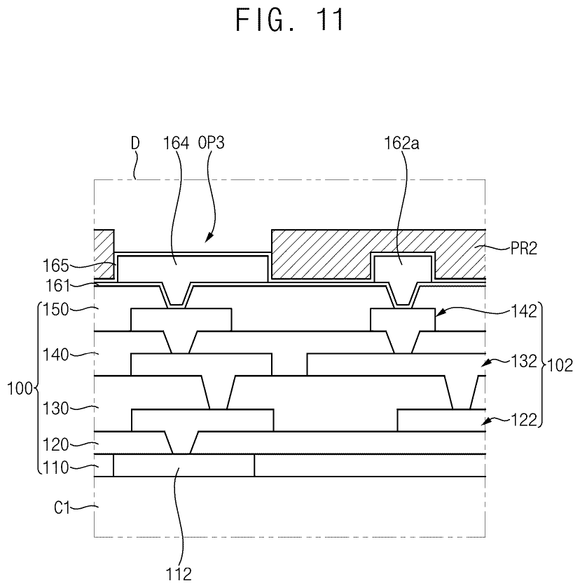

As illustrated in FIGS. 10 and 11, the first photoresist pattern PR1 may be removed. After removing the first photoresist pattern PR1, a second seed layer 165 may be formed on the fifth lower insulating layer 150, and a second photoresist pattern PR2 having fourth openings OP3 that expose the heat dissipation pad regions may be formed on the second seed layer 165.

In some examples, after removing the first photoresist pattern PR1, portions of the first seed layer 161 exposed between the upper bonding pads may be removed. Alternatively, to simplify the process, the process of removing the exposed portions of the first seed layer 161 may be omitted.

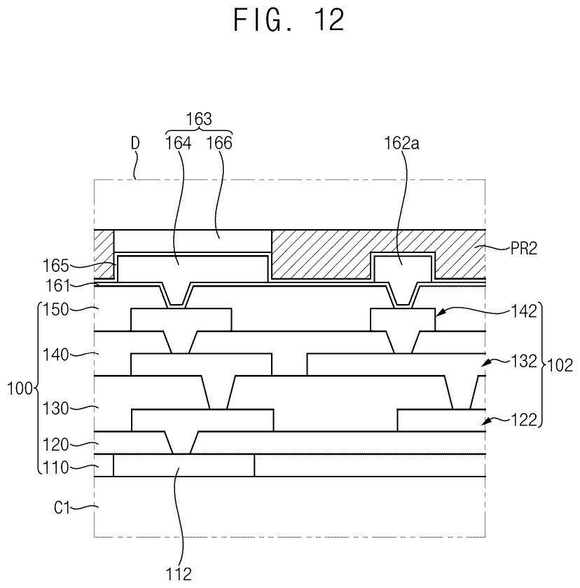

As illustrated in FIG. 12, upper heat dissipation pads 166 may be formed in the fourth openings OP3 of the second photoresist pattern PR2 by a plating process. The upper heat dissipation pads 166 may be formed of and/or include a metal material. The upper heat dissipation pad may be formed of and/or include the same material as the lower heat dissipation pad 164.

As illustrated in FIGS. 13 to 15, the second photoresist pattern PR2 may be removed and, after removing the second photoresist pattern PR2, portions of the second seed layer 165 and the first seed layer 161 exposed between the upper bonding pads and the upper heat dissipation pads 163 may be removed. Accordingly, the heat dissipation pad 163 including the lower heat dissipation pad 164 and the upper heat dissipation pad 166 sequentially stacked on the first uppermost redistribution wiring disposed in the first heat dissipation region HR1 of the first region MR may be formed. A height H2 of the heat dissipation pad 163 from the first redistribution wiring layer 100 may be greater than a height of the first bonding pad 162a from the first redistribution wiring layer 100.

Thus, the plurality of first bonding pads 162a may be formed in the first region MR on the upper surface of the first redistribution wiring layer 100, and the plurality of second bonding pads 162b may be formed in the second region MR on the upper surface of the first redistribution wiring layer 100. The at least one heat dissipation pad 163 may be formed in the first heat dissipation region HR1 of the first region MR on the upper surface of the first redistribution wiring layer 100. The plurality of first bonding pads 162a may be formed in the first heat dissipation region HR1 and the second heat dissipation region HR2 of the first region MR on the upper surface of the first redistribution wiring layer 100.

Electrical signals may be transmitted through the first and second bonding pads 162a and 162b. The heat dissipation pad 163 may be a dummy pad through which electrical signals are not transmitted.

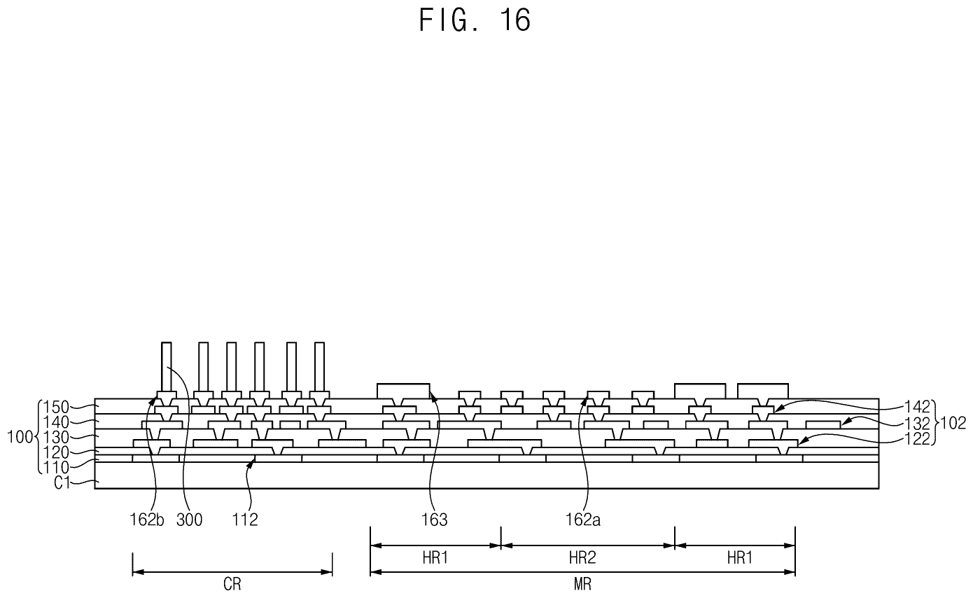

Referring to FIG. 16, the plurality of conductive through vias 300 may be formed in the second region CR on the upper surface of the first redistribution wiring layer 100. The conductive through vias 300 may be electrically connected to the first redistribution wirings 102 of the first redistribution wiring layer 100.

In some examples, a photoresist layer may be formed on the upper surface of the first redistribution wiring layer 100, and an exposure process may be performed on the photoresist film to form a photoresist pattern having openings that expose through-via regions in the second region CR on the upper surface of the first redistribution wiring layer 100. The openings in the photoresist pattern may expose at least portions of the plurality of second bonding pads 162b in the second region CR.

Then, the openings of the photoresist pattern may be filled with a conductive material to form the conductive through vias 300. For example, an electrolytic plating process may fill the openings of the photoresist pattern to form the conductive through vias 300. Subsequently, the photoresist pattern may be removed through a strip process.

Accordingly, the conductive through vias 300 may extend upward from the second bonding pads 162b on the first redistribution wirings 102 of the first redistribution wiring layer 100, that is, the third uppermost redistribution wirings 142, respectively. In some examples, a diameter of the conductive through via 300 may be within a range of 30 μm to 100 μm, and a height of the conductive through via 300 may be within a range of 200 μm to 300 μm.

Referring to FIGS. 17 to 19, at least one semiconductor chip 200 may be disposed in the first region MR on the upper surface of the first redistribution wiring layer 100.

In example embodiments, the semiconductor chip 200 may be mounted in the first region MR of the first redistribution wiring layer 100. The semiconductor chip 200 may be mounted on the upper surface of the first redistribution wiring layer 100 by a flip chip bonding method. The semiconductor chip 200 may be arranged such that a front surface 202 on which chip pads 210 are formed, that is, an active surface, faces the first redistribution wiring layer 100.

The semiconductor chip may be a logic chip including logic circuits. The logic chip may be a controller that controls memory chips. The semiconductor chip may be an ASIC as a host such as CPU, NPU, GPU, or SOC, or a processor chip such as an application processor AP. For example, when the semiconductor chip is provided for a mobile AP, the semiconductor chip may be a system on chip (SOC) that includes IP blocks such as CPU, GPU, etc. in one chip. The semiconductor chip may include the IP block and may include at least one first heating zone HZ1 configured to emit first heat and a second heating zone HZ2 configured to emit second heat less than the first heat. The first heating zone HZ1 may be a heat source area of the semiconductor chip 200 where relatively large amounts of heat are emitted.

In example embodiments, the chip pads 210 of the semiconductor chip 200 may include signal chip pads 210a and dummy chip pads 210b. The signal chip pads 210a may be chip pads through which electrical signals are transmitted, and the dummy chip pads 210b may be dummy chip pads through which electrical signals are not transmitted. At least one dummy chip pad 210b may be formed in the first heating zone HZ1 on the front surface 202 of the semiconductor chip 200. The signal chip pads 210a may be formed in the first heating zone HZ1 and the second heating zone HZ2 on the front surface 202 of the semiconductor chip 200.

In example embodiments, the semiconductor chip 200 may be electrically connected to the first redistribution wirings 102 of the first redistribution wiring layer 100 via conductive bumps 220. The conductive bumps 220 may include micro bumps (uBumps). The conductive bumps 220 may be formed on the signal chip pads 210a, respectively. The conductive bump 220 may be interposed between the signal chip pad 210a and the first bonding pad 163a. In this case, the signal chip pad 210a may include a pillar pad, and the conductive bump 220 may include a solder pad formed on the pillar pad. The pillar pad may be formed of and/or include copper (Cu), nickel (Ni), palladium (Pd), platinum (Pt), gold (Au), cobalt (Co), or an alloy thereof. The solder pad may be formed of and/or include tin (Sn), indium (In), antimony (Sb), copper (Cu), silver (Ag), zinc (Zn), lead (Pb), or an alloy thereof.

As illustrated in FIG. 19, the semiconductor chip 200 may be disposed to be in contact with the at least one heat dissipation pad 163. The semiconductor chip 200 may be disposed on the first redistribution wiring layer 100 such that the front surface 202 at least partially contacts the at least one heat dissipation pad 163. The dummy chip pad 210b may contact the heat dissipation pad 163. Accordingly, heat from the first heating zone HZ1 of the semiconductor chip 200 may be transferred to the first heat dissipating region HR1 of the first redistribution wiring layer 100 through the dummy chip pad 210b and the heat dissipation pad 163, and then, may be dissipated to the outside.

In some examples, a thickness of the semiconductor chip 200 may be within a range of 100 μm to 300 μm. Heat from the first heating zone HZ1 of the semiconductor chip 200 may be effectively dissipated to the outside by the dummy heat dissipation pads 163. Since the heat dissipation characteristics of the semiconductor package are improved by the heat dissipation pads 163, the thickness of the semiconductor chip 200 may be made smaller, thereby reducing a thickness of the entire package.

Underfill members 230 may be underfilled between the semiconductor chip 200 and the first redistribution wiring layer 100. The underfill member 230 may include a material with relatively high fluidity when applied to effectively fill a small space between the semiconductor chip 200 and the first redistribution wiring layer 100. In some examples, the underfill member 230 may include an adhesive containing an epoxy material.

It will be understood that the thicknesses of the first redistribution wiring layer 100 and the semiconductor chip, the arrangements of the conductive through vias and the heat dissipation pads, etc. are provided as examples, and the present inventive concept is not limited thereto. The thicknesses of the first redistribution wiring layer and the semiconductor chip, the arrangements of the conductive through vias and the heat dissipation pads, etc. may be determined in consideration of the thickness, warpage, heat dissipation characteristics, etc. of the entire package.

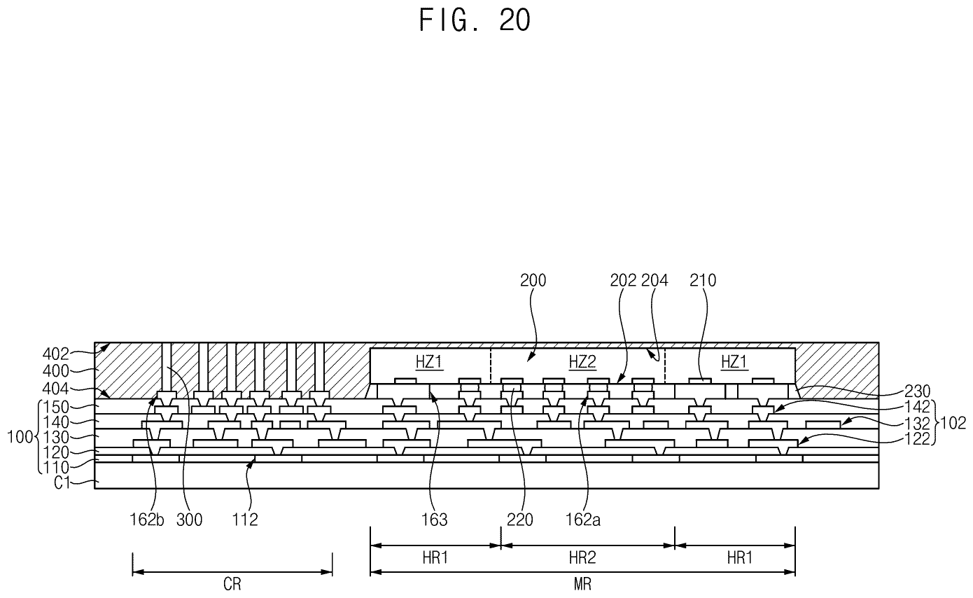

Referring to FIG. 20, a molding member 400 may be formed on the upper surface of the first redistribution wiring layer 100 to cover the semiconductor chip 200 and the plurality of conductive through vias 300.

In some examples, the molding member 400 may be formed of and/or include an epoxy mold compound (EMC). The molding member 400 may be formed of and/or include UV resin, polyurethane resin, silicone resin, silica filler, etc.

In example embodiments, a molding layer may be formed on the upper surface of the first redistribution wiring layer 100 to cover the semiconductor chip 200 and the conductive through vias 300 and an upper portion of the molding layer may be removed to expose upper surfaces of the conductive through vias 300.

Accordingly, the semiconductor chip 200 may be covered by the molding member 400, and the conductive through vias 300 may be exposed at an upper surface 402 of the molding member 400.

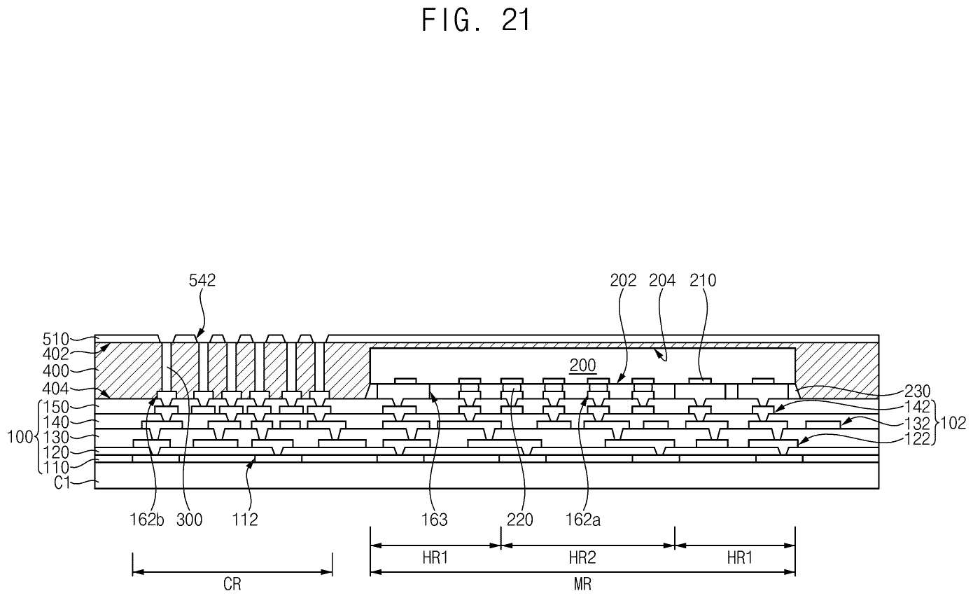

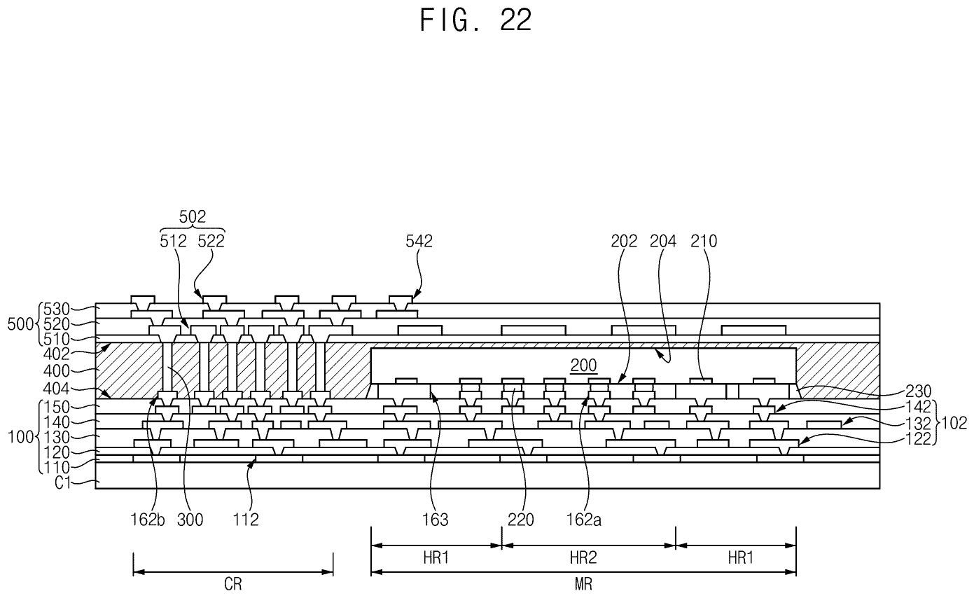

Referring to FIGS. 21 and 22, a second redistribution wiring layer 500 having second redistribution wirings 502 may be formed on the upper surface 402 of the molding member 400. The second redistribution wirings 502 may be electrically connected to the conductive through vias 300. The second redistribution wiring layer 500 may be disposed over the semiconductor chip 200.

As illustrated in FIG. 21, after a first upper insulating layer 510 is formed on the upper surface 402 of the molding member 400, the first upper insulating layer 510 may be patterned to form openings 511 that expose the conductive through vias 300. The openings 511 of the patterned first upper insulating layer 510 may expose upper surfaces of the conductive through vias 300, respectively. The first upper insulating layer 510 may include a polymer layer, a dielectric layer, etc. In some examples, the first upper insulating layer 510 may be formed by a vapor deposition process, a spin coating process, etc.

A seed layer may then be formed on portions of the conductive through vias 300 and in the openings 511. After forming the seed layer on portions of the conductive through vias 300 and in the openings 511, the seed layer may be patterned, and an electrolytic plating process may be performed to form first upper redistribution wirings 512. Accordingly, at least portions of the first upper redistribution wirings 512 may contact the conductive through vias 300 through the openings. The first upper redistribution wirings 512 may be formed of and/or include aluminum (Al), copper (Cu), tin (Sn), nickel (Ni), gold (Au), platinum (Pt), or an alloy thereof.

Similarly, after forming a second upper insulating layer 520 on the first upper insulating layer 510, the second upper insulating layer 520 may be patterned to form openings that expose the first upper redistribution wirings 512. Subsequently, second upper redistribution wirings 522 may be formed on the second upper insulating layer 520 through the openings to directly contact the first upper redistribution wirings 512.

After forming a third upper insulating layer 530 on the second upper insulating layer 520, the third upper insulating layer 530 may be patterned to form openings that expose the second upper redistribution wirings 522. The second upper redistribution wirings 522 exposed by the openings may be outermost redistribution wirings. A portion of the outermost redistribution wiring may include a redistribution pad portion.

Then, as shown in FIG. 22, an upper bump pad 542 such as UBM may be formed on the redistribution pad portion. The third upper insulating layer 530 may function as a passivation layer.

Accordingly, the second redistribution wiring layer 500 having the second redistribution wirings 502 may function as a backside redistribution wiring layer (BRDL) and may be formed on the molding member 400. The second redistribution wiring layer 500 may include the stacked first, second, and third upper insulating layers 510, 520 and 530 and the second redistribution wirings 502 in the first to third upper insulating layers 510, 520 and 530. The second redistribution wirings 502 may include the first and second upper redistribution wirings 512 and 522.

It will be understood that the number, sizes, and arrangements of the upper insulating layers and the upper redistribution wirings of the second redistribution wiring layer are provided as examples, and the present inventive concept is not limited thereto.

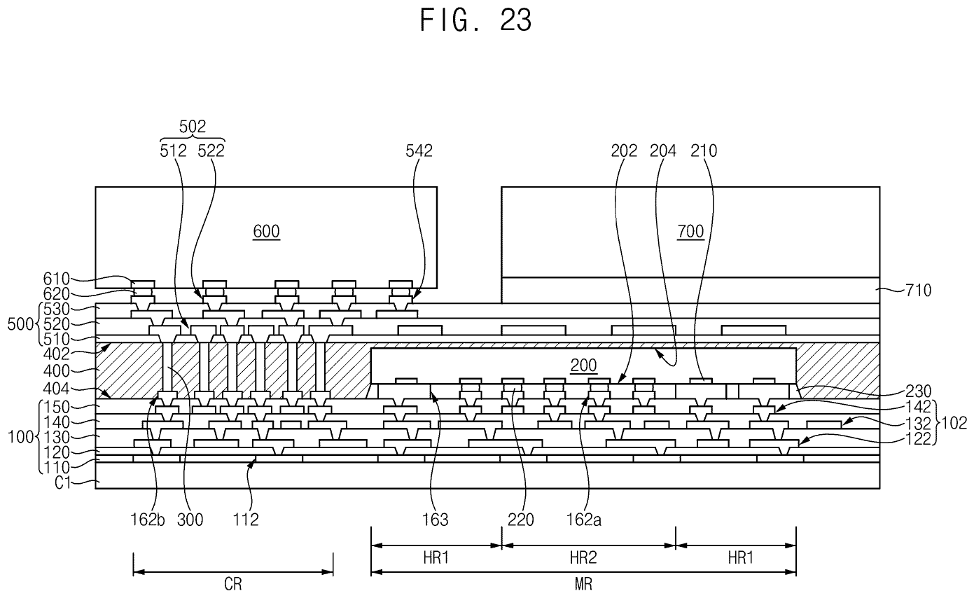

Referring to FIG. 23, an upper package which may include upper semiconductor chip 600 and a heat dissipation block 700 may be stacked on the second redistribution wiring layer 500.

In example embodiments, the upper semiconductor chip 600 may be mounted on an upper surface of the second redistribution wiring layer 500 by a flip chip bonding method. The upper semiconductor chip 600 may be disposed such that a front surface on which upper chip pads 610 are formed, that is, an active surface, faces the second redistribution wiring layer 500. The upper chip pads 610 of the upper semiconductor chip 600 may be electrically connected to the second redistribution wirings 502 of the second redistribution wiring layer 500 through second conductive bumps 620.

The upper semiconductor chip 600 may be arranged to at least partially overlap the plurality of conductive through vias 300. The upper semiconductor chip 600 may include a memory chip. The memory chip may include various types of memory circuits, such as DRAM, SRAM, flash, PRAM, ReRAM, FeRAM, or MRAM.

Although one upper semiconductor chip is illustrated as being mounted on the second redistribution wiring layer 500, it is not limited thereto, and for example, the upper package may include a package substrate and at least one upper semiconductor chip mounted on the package substrate, and the package substrate of the upper package may be mounted on the second redistribution wiring layer via the second conductive bumps.

The heat dissipation block 700 may be disposed on the second redistribution wiring layer 500. The heat dissipation block 700 may be disposed to one side of the upper semiconductor chip 600 on the second redistribution wiring layer 500. The heat dissipation block 700 may be arranged to be spaced apart from the upper semiconductor chip 600 on the second redistribution wiring layer 500.

In example embodiments, the heat dissipation block 700 may be disposed over the lower semiconductor chip 200. The heat dissipation block 700 may be arranged to partially overlap the semiconductor chip 200. When viewed in a plan view, one side of the semiconductor chip 200 adjacent to the conductive through vias 300 may not overlap with the heat dissipation block 700. When the heat source area where heat is concentrated, such as a CPU or GPU block, is provided on one side of the semiconductor chip 200, the heat source area may not overlap the heat dissipation block 700 and a thermal resistance through the second redistribution wiring layer 500 may be higher relative to the areas in which the heat dissipation block overlaps causing the heat dissipation to deteriorate through the second redistribution wiring layer. Meanwhile, heat from the heat source area of the semiconductor chip 200 may be effectively dissipated to the outside (e.g., external to the semiconductor package 10) through the first redistribution wiring layer 100 by the dummy heat dissipation pads 163. Accordingly, the heat dissipation characteristics of the semiconductor package 10 may be improved.

The heat dissipation block 700 may be attached to the upper surface of the second redistribution wiring layer 500 by an adhesive film 710 such as a non-conductive adhesive film (NCF). In some examples, the heat dissipation block 700 may be formed of and/or include a material with excellent thermal conductivity. The heat dissipation block 700 may be formed of and/or include a metal such as copper or a silicon material. A height of the heat dissipation block 700 from the second redistribution wiring layer 500 may be the same as a height of the upper semiconductor chip 600 from the second redistribution wiring layer 500. A thickness of the upper semiconductor chip 600 may be within a range of 0.3 mm to 0.5 mm, and a thickness of the first heat dissipation block 700 may be within the range of 0.4 mm to 0.65 mm. A diameter of the second conductive bumps 620 may be within a range of 70 μm to 200 μm.

External connection members 800 (see FIG. 1) may be formed on the lower surface of the first redistribution wiring layer 100. The external connection members 800, such as solder balls or solder bumps, may be formed on the lower bonding pads 112 of the first redistribution wiring layer 100, respectively.

The lower redistribution wiring layer may be separated into individual lower redistribution wiring layers 100 through a sawing process to complete the fan-out wafer level semiconductor package 10 of FIG. 1 including the molding member 400, the lower redistribution wiring layer 100 formed on the lower surface 404 of the molding member 400, and the upper redistribution wiring layer 500 formed on the upper surface 402 the molding member 400.

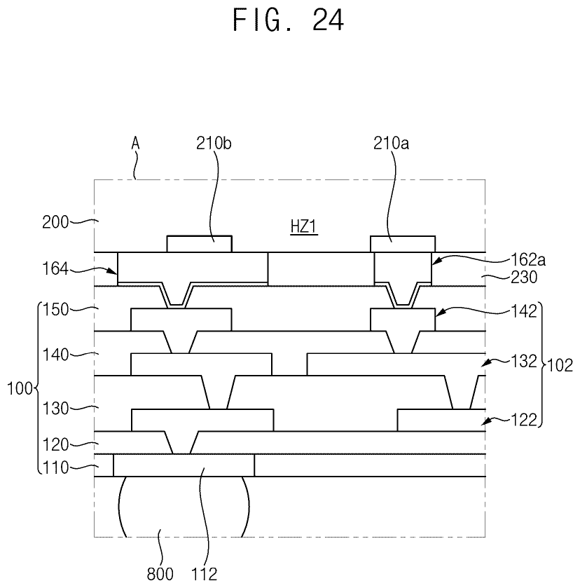

FIG. 24 is a cross-sectional view illustrating a semiconductor package in accordance with example embodiments. FIG. 24 is an enlarged cross-sectional view illustrating portion ‘A’ in FIG. 1. The semiconductor package may be substantially the same as the semiconductor package described with reference to FIGS. 1 to 4 except for a structure of a heat dissipation pad and a mounting manner of a semiconductor chip. Thus, same reference numerals may be used to refer to the same or like elements and any further repetitive explanation concerning the above elements may be omitted.

Referring to FIG. 24, chip pads 210 of a semiconductor chip 200 may contact upper bonding pads disposed on uppermost redistribution wirings 142 of first redistribution wirings 102. The upper bonding pads may include a plurality of first bonding pads 162a and at least one heat dissipation pad 164 provided in a chip mounting region MR. A height of the heat dissipation pad 164 from the first redistribution wiring layer 100 may be the same as a height of the first bonding pad 162a from the first redistribution wiring layer 100. The heat dissipation pad 164 and the plurality of first bonding pads 162a may be formed by the same plating process (e.g., a single process may form the material constituting the heat dissipation pad 164 and the first bonding pads 162a).

In example embodiments, the semiconductor chip 200 may be disposed such that a front surface 202 on which the chip pads 210 are formed, that is, an active surface, faces the first redistribution wiring layer 100. The chip pads 210 of the semiconductor chip 200 may include signal chip pads 210a and dummy chip pads 210b. The signal chip pads 210a may contact the first bonding pads 162a respectively, and the dummy chip pad 210b may contact the heat dissipation pad 164. In this case, the signal chip pad 210a and the dummy chip pad 210b may include pillar pads. The pillar pads may contact the first bonding pads 162a and the heat dissipation pad 164, respectively.

Accordingly, heat from a first heating zone HZ1 of the semiconductor chip 200 may be dissipated to the outside through a first redistribution wiring layer 100 through the dummy chip pad 210b and the heat dissipation pad 164.

Hereinafter, a method of manufacturing the semiconductor package of FIG. 24 will be described.

First, processes that are the same as or similar to the processes as described with reference to FIGS. 5 to 9 may be performed to form a photoresist pattern PR1 having openings that expose upper bonding pad regions on a first seed layer 161 on a fifth lower insulating layer 150, and upper bonding pads may be formed in the openings of the first photoresist pattern PR1 through a plating process. The upper bonding pads may include a plurality of first bonding pads 162a formed in first openings OP1 and a lower heat dissipation pad 164 formed in a second opening OP2 of the first photoresist pattern PR1.

Then, after removing the first photoresist pattern PR1, portions of the first seed layer 161 exposed between the upper bonding pads may be removed. Accordingly, the lower heat dissipation pad 164 may be formed on the first uppermost redistribution wiring disposed in a first heat dissipation region HR1 of a chip mounting region MR. A height of the lower heat dissipation pad 164 from the first redistribution wiring layer 100 may be the same as a height of the first bonding pad 162a from the first redistribution wiring layer 100.

Then, processes that are the same as or similar to the processes described with reference to FIG. 16 may be performed to form a plurality of conductive through vias 300 that extend upward from second bonding pads 162b on the third uppermost redistribution wirings 142 in a connector region CR of the first redistribution wiring layer 100.

Then, processes the same as or similar to the processes described with reference to FIGS. 17 to 19 may be performed to dispose at least one semiconductor chip 200 in the first region MR on the upper surface of the first redistribution wiring layer 100.

In example embodiments, the semiconductor chip 200 may be disposed such that a front surface 202 on which chip pads 210 are formed, that is, an active surface, faces the first redistribution wiring layer 100. The chip pads 210 of the semiconductor chip 200 may include signal chip pads 210a and dummy chip pads 210b. The signal chip pads 210a may contact the first bonding pads 162a respectively, and the dummy chip pad 210b may contact the heat dissipation pad 164.

Accordingly, heat from a first heating zone HZ1 of the semiconductor chip 200 may be dissipated to the outside through the first redistribution wiring layer 100 through the dummy chip pad 210b and the heat dissipation pad 164.

Then, processed the same as or similar to the processes described with reference to FIGS. 20 to 23 may be performed to form a second redistribution wiring layer 500 having second redistribution wirings 502 on an upper surface 402 of a molding member 400, and an upper semiconductor chip 600 as an upper package and a heat dissipation block 700 may be stacked on the second redistribution wiring layer 500.

Then, external connection members 800 (see FIG. 24) may be formed on a lower surface of the first redistribution wiring layer 100 to complete the semiconductor package of FIG. 24.

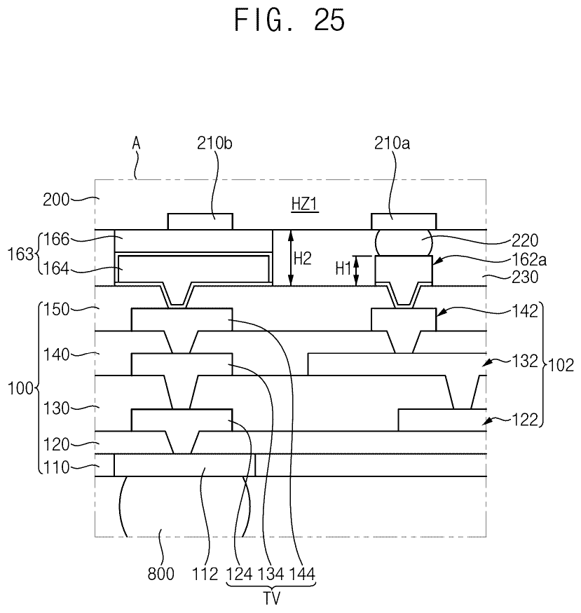

FIG. 25 is a cross-sectional view illustrating a semiconductor package in accordance with example embodiments. FIG. 25 is an enlarged cross-sectional view illustrating portion ‘A’ in FIG. 1. The semiconductor package may be substantially the same as the semiconductor package described with reference to FIGS. 1 to 4 except for a configuration of a first redistribution wiring layer. Thus, same reference numerals may be used to refer to the same or like elements and any further repetitive explanation concerning the above elements will be omitted.

Referring to FIG. 25, a first redistribution wiring layer 100 may include a heat dissipation via structure TV therein, and at least one heat dissipation pad 163 may be disposed on the heat dissipation via structure TV The heat dissipation via structure TV may be a dummy via structure through which electrical signals are not transmitted.

In example embodiments, the heat dissipation via structure TV may include stacked first, second, and third vias 124, 134 and 144. The first, second, and third vias 124, 134 and 144 may be formed by processes the same as the processes of forming the first, second, and third lower redistribution wirings 122, 132, and 142, respectively. In this case, the heat dissipation pad 163 may be formed on the third via 144, which is an uppermost via. Accordingly, heat from a first heating zone HZ1 of the semiconductor chip 200 may be dissipated to the outside through the heat dissipation pad 163 and the heat dissipation via structure TV.

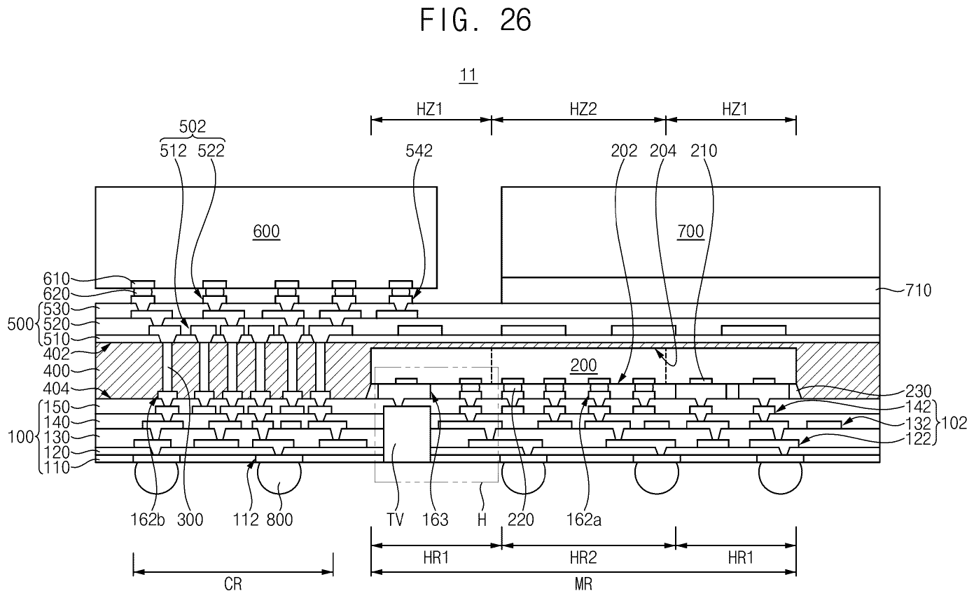

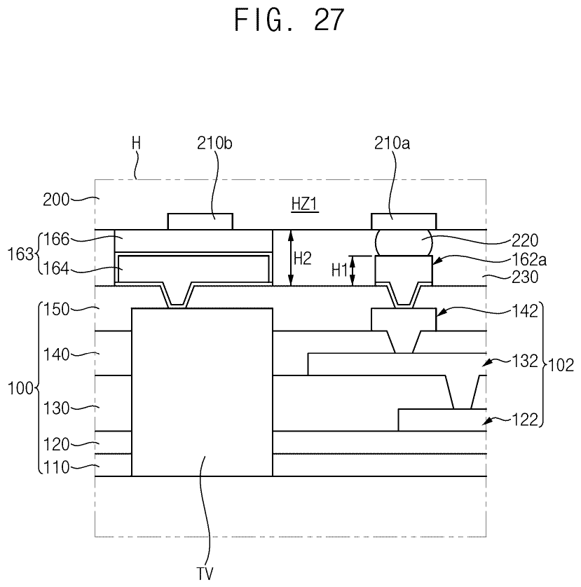

FIG. 26 is a cross-sectional view illustrating a semiconductor package in accordance with example embodiments. FIG. 27 is an enlarged cross-sectional view illustrating portion ‘H’ in FIG. 26. The semiconductor package may be substantially the same as the semiconductor package described with reference to FIGS. 1 to 4 except for a heat dissipation via of a first redistribution wiring layer. Thus, same reference numerals may be used to refer to the same or like elements and any further repetitive explanation concerning the above elements will be omitted.

Referring to FIGS. 26 and 27, a first redistribution wiring layer 100 of a semiconductor package 11 may include at least one heat dissipation via TV, and at least one heat dissipation pad 163 may be disposed on the at least one heat dissipation via TV. The heat dissipation via TV may be a dummy via structure through which electrical signals are not transmitted.

In example embodiments, the heat dissipation via TV may at least partially penetrate the first redistribution wiring layer 100. The heat dissipation via TV may be formed to penetrate through all or a portion of first to fifth lower insulating layers 110, 120, 130, 140, and 150 of the first redistribution wiring layer 100.

The heat dissipation pad 163 may be disposed on the heat dissipation via TV. The heat dissipation pad 163 may be thermally connected to the heat dissipation via TV in the first redistribution wiring layer 100. The fifth lower insulating layer 150 may include an opening that exposes an upper surface of the heat dissipation via TV, and the heat dissipation pad 163 may be connected to the heat dissipation via TV through the opening of the fifth lower insulating layer 150. A lower surface of the heat dissipation via TV may be exposed from a lower surface of the first redistribution wiring layer 100.

Accordingly, heat from a first heating zone HZ1 of the semiconductor chip 200 may be effectively dissipated to the outside through the heat dissipation pad 163 and the heat dissipation via TV.

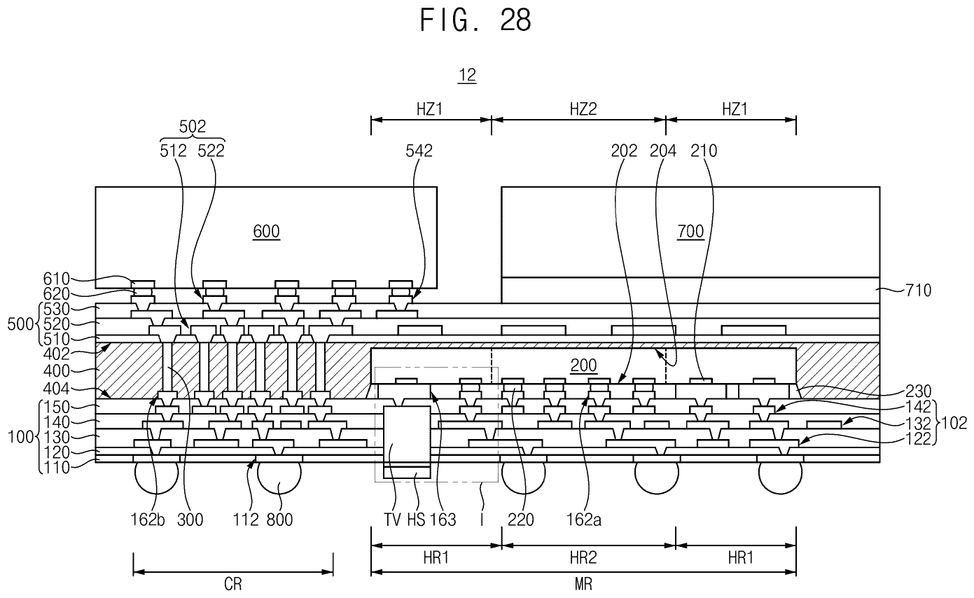

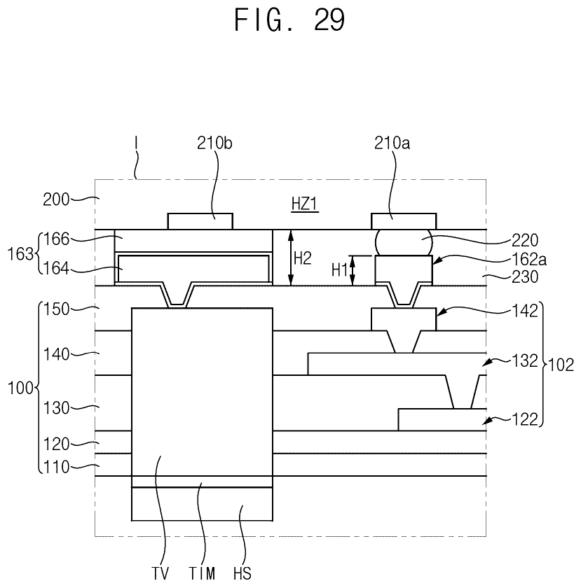

FIG. 28 is a cross-sectional view illustrating a semiconductor package in accordance with example embodiments. FIG. 29 is an enlarged cross-sectional view illustrating portion ‘I’ in FIG. 28. The semiconductor package may be substantially the same as the semiconductor package described with reference to FIGS. 26 and 27 except for an additional lower heat dissipation block on a heat dissipation via of a first redistribution wiring layer. Thus, same reference numerals may be used to refer to the same or like elements and any further repetitive explanation concerning the above elements will be omitted.

Referring to FIGS. 28 and 29, a semiconductor package 12 may further include at least one lower heat dissipation block HS disposed on at least one heat dissipation via TV in a first redistribution wiring layer 100.

In example embodiments, the lower heat dissipation block HS may be disposed on a lower surface of the first redistribution wiring layer 100. The lower heat dissipation block HS may be arranged to overlap the heat dissipation via TV within the first redistribution wiring layer 100.

The lower heat dissipation block HS may be attached to the lower surface of the heat dissipation via TV exposed at the lower surface of the first redistribution wiring layer 100 using an adhesive film containing a thermal interface material (TIM). In some examples, the lower heat dissipation block HS may include a material having excellent thermal conductivity. The lower heat dissipation block HS may include a metal such as copper or a silicon material. A height of the lower heat dissipation block HS from the first redistribution wiring layer 100 may be less than or equal to a height of an external connection member 800 from the first redistribution wiring layer 100.

Accordingly, heat from a first heating zone HZ1 of a semiconductor chip 200 may be effectively dissipated to the outside through a heat dissipation pad 163, the heat dissipation via TV, and the lower heat dissipation block HS.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a first redistribution wiring layer including a first region and a second region that are spaced apart from each other, the first redistribution wiring layer having first redistribution wirings;
a plurality of first bonding pads and at least one heat dissipation pad disposed in the first region on an upper surface of the first redistribution wiring layer, and a plurality of second bonding pads disposed in the second region on the upper surface of the first redistribution wiring layer;
a semiconductor chip mounted in the first region on the first redistribution wiring layer such that at least part of a front surface of the semiconductor chip on which chip pads are formed contacts the at least one heat dissipation pad, the semiconductor chip being electrically connected to the plurality of first bonding pads;
a molding member covering the semiconductor chip on the first redistribution wiring layer;
a plurality of conductive through vias with each conductive through via respectively penetrating the molding member on the second region and electrically connected to a respective bonding pad of the plurality of second bonding pads; and
a second redistribution wiring layer disposed on the molding member and having second redistribution wirings with at least one second redistribution wiring electrically connected to a respective conductive through via of the plurality of conductive through vias.

2. The semiconductor package of claim 1, wherein the semiconductor chip is mounted on the first redistribution wiring layer via conductive bumps that are disposed on the chip pads.

3. The semiconductor package of claim 2, wherein the conductive bumps are respectively disposed on the plurality of first bonding pads.

4. The semiconductor package of claim 3, wherein the conductive bumps are formed on a plurality of signal chip pads among the chip pads of the semiconductor chip.

5. The semiconductor package of claim 1, wherein a signal chip pad of the plurality of chip pads contacts a first bonding pad of the plurality of first bonding pads.

6. The semiconductor package of claim 1, wherein at least one dummy chip pad among the chip pads of the semiconductor chip is in contact with the at least one heat dissipation pad.

7. The semiconductor package of claim 6, wherein the semiconductor chip has a first heating zone configured to emit first heat and a second heating zone configured to emit second heat less than the first heat, and the at least one dummy chip of the semiconductor chip is disposed in the first heating zone.

8. The semiconductor package of claim 1, further comprising:
an upper semiconductor chip disposed on the second redistribution wiring layer and electrically connected to the second redistribution wiring layers; and
a heat dissipation block disposed on the second redistribution wiring layer.

9. The semiconductor package of claim 1, wherein the first redistribution wiring layer further includes a heat dissipation via that at least partially penetrates the first redistribution wiring layer, and the at least one heat dissipation pad is provided on the heat dissipation via.

10. The semiconductor package of claim 9, further comprising:
a lower heat dissipation block disposed on the heat dissipation via on a lower surface of the first redistribution wiring layer.

11. A semiconductor package, comprising:
a first redistribution wiring layer including a chip mounting region and a connector region that are spaced apart from each other, and the first redistribution wiring layer having first redistribution wirings;
a plurality of first bonding pads and a plurality of second bonding pads provided on uppermost redistribution wirings of the first redistribution wirings at an upper surface of the first redistribution wiring layer, the plurality of first bonding pads disposed in the chip mounting region and the plurality of second bonding pads disposed in the connector region;
at least one heat dissipation pad disposed in the chip mounting region at the upper surface of the first redistribution wiring layer;
a semiconductor chip mounted in the chip mounting region on the first redistribution wiring layer such that a front surface on which chip pads are formed faces the first redistribution wiring layer, the semiconductor chip being in contact with the at least one heat dissipation pad;
a molding member covering the semiconductor chip on the first redistribution wiring layer;
a plurality of conductive through vias respectively penetrating the molding member and each conductive through via respectively disposed on a respective second bonding pad of the plurality of second bonding pads on the connector region; and
a second redistribution wiring layer disposed on the molding member and having second redistribution wirings with each second redistribution wiring electrically connected to a respective conductive through via of the plurality of conductive through vias.

12. The semiconductor package of claim 11, wherein the semiconductor chip is mounted on the first redistribution wiring layer via conductive bumps that are disposed on the chip pads.

13. The semiconductor package of claim 12, wherein the conductive bumps are respectively disposed on the plurality of first bonding pads.

14. The semiconductor package of claim 13, wherein the conductive bumps are formed on a plurality of signal chip pads among the chip pads of the semiconductor chip.

15. The semiconductor package of claim 11, wherein a plurality of signal chip pads among the chip pads of the semiconductor chip contact the plurality of first bonding pads, respectively.

16. The semiconductor package of claim 11, wherein at least one dummy chip pad among the chip pads of the semiconductor chip is in contact with the at least one heat dissipation pad.

17. The semiconductor package of claim 16, wherein the semiconductor chip has a first heating zone configured to emit first heat and a second heating zone configured to emit second heat less than the first heat, and the at least one dummy chip of the semiconductor chip is disposed in the first heating zone.

18. The semiconductor package of claim 11, further comprising:
an upper semiconductor chip disposed on the second redistribution wiring layer and electrically connected to the second redistribution wiring layers; and
a heat dissipation block disposed on the second redistribution wiring layer.

19. The semiconductor package of claim 11, wherein the first redistribution wiring layer further includes a heat dissipation via that at least partially penetrates the first redistribution wiring layer, and the at least one heat dissipation pad is thermally connected to the heat dissipation via.

20. A semiconductor package, comprising:
a first redistribution wiring layer including a chip mounting region and a connector region that are spaced apart from each other, and having first redistribution wirings;
a plurality of first bonding pads and at least one heat dissipation pad respectively disposed in the chip mounting region on the first redistribution wiring layer, and a plurality of second bonding pads disposed in the connector region on the first redistribution wiring layer;
a semiconductor chip mounted in the chip mounting region on the first redistribution wiring layer such that a front surface on which chip pads are formed faces the first redistribution wiring layer;
a molding member covering the semiconductor chip on the first redistribution wiring layer;
a plurality of conductive through vias each penetrating the molding member and respectively disposed on a respective second bonding pad of the plurality of second bonding pads in the connector region; and
a second redistribution wiring layer disposed on the molding member and having second redistribution wirings with at least one electrically connected to a respective conductive through via of the plurality of conductive through vias,
wherein the semiconductor chip includes a first heating zone configured to emit first heat and a second heating zone configured to emit second heat less than the first heat, and
wherein at least one dummy chip pad among the chip pads is provided in the first heating zone and contacts the at least one heat dissipation pad.
